(19) United States
(12) Patent Application Publication
(10) Pub. No.: US 2024/0402314 A1
(43) Pub. Date: Dec. 5, 2024

(54) PHOTODETECTION ELEMENT AND PHOTODETECTION DEVICE

(71) Applicant: SONY SEMICONDUCTOR SOLUTIONS CORPORATION, KANAGAWA (JP)

(72) Inventors: NOBUO NAKAMURA, KANAGAWA (JP); ATSUSHI TODA, KANAGAWA (JP)

(21) Appl. No.: 18/700,103

(22) PCT Filed: Jun. 9, 2022
(86) PCT No.: PCT/JP2022/023333

§ 371 Date: Apr. 10, 2024

(30) Foreign Application Priority Data
Oct. 18, 2021 (JP) 2021-170488

(51) Int. Cl. G01S 7/4914; G01S 7/481; G01S 17/89; G01S 17/931

(52) U.S. Cl. CPC G01S 7/4914; G01S 7/4815; G01S 7/4816; G01S 17/89; G01S 17/931

(57) ABSTRACT

[Problem] Provided are a photodetection element and a photodetection device that can be further downsized.

[Solution] A photodetection element according to an embodiment includes: a light emitting unit configured to emit measurement light in a first direction to a measurement target and emit reference light in a second direction different from the first direction; and a photoelectric conversion element configured to receive the reference light and performs photoelectric conversion.

### TECHNICAL FIELD

Embodiments of the present invention relate to a detection element and a photodetection device.

### BACKGROUND ART

Conventional optical detection systems include a plurality of types such as a direct ToF (dToF) system that measures a round-trip time of light and measures a distance, an indirect ToF (iToF) system that measures a phase difference of light and measures a distance, and a frequency modulated continuous wave (FMCW) system that performs frequency modulation (chirp) of an optical frequency and measures a distance from a beat frequency of reference light and reflected light. Among them, the FMCW system has characteristics such as low power consumption, high definition, advanced distance measurement accuracy, and high background light resistance, and has been researched and developed and put to practical use in recent years.

In addition, in a focal plane array (FPA) type FMCW system in the FMCW system, a transceiver (TX) unit that emits light and a receiver (RX) unit that receives light are arranged at different positions on the chip. Therefore, a large chip area is required, and the photodetection element becomes large. In addition, there is also known a device in which the TX unit and the RX unit are configured by the same lattice-shifted photonic crystal waveguide (lattice-shifted PCW, LSPCW). However, although the emission angle can be controlled by electronically changing the wavelength in the long side direction, the light cannot be collected in the short side direction, and thus it is necessary to attach a prism lens to collect the light. Therefore, the photodetection device becomes large.

### CITATION LIST

### Patent Document

Patent Document 1: Japanese Patent Application Laid-Open No. 11-352215

### SUMMARY OF THE INVENTION

### Problems to be Solved by the Invention

Therefore, the present disclosure provides a photodetection element and a photodetection device that can be further downsized.

### Solutions to Problems

In order to solve the above problem, according to the present disclosure, there is provided a photodetection element, including:
a light emitting unit configured to emit measurement light in a first direction to a measurement target and emit reference light in a second direction different from the first direction; and
a photoelectric conversion element configured to receive the reference light and performs photoelectric conversion.

The photoelectric conversion element may further receive return light of the measurement light from the measurement target, and may photoelectrically convert the reference light and the return light.

The second direction may be a direction opposite to the first direction.

The light emitting unit may emit the measurement light from a first region to a measurement target, and emit the reference light from a second region different from the first region.

The second region may be a region of a surface opposite to a traveling direction of the measurement light emitted from the first region.

The light emitting unit may emit light having a wavelength longer than 700 nm.

The light emitting unit may be a material having a band gap equal to or more than energy corresponding to the wavelength of the emitted light.

The light emitting unit may include at least one of silicon (Si), silicon nitride (Si₃N₄), gallium nitrate (Ga₂O₃), and germanium (Ge).

The light emitting unit may be a diffraction grating including a diffraction portion, and the measurement light may be emitted from the diffraction grating.

The light emitting unit may include an optical switch using a micro electro mechanical system (MEMS).

The light emitting unit may emit chirped light having a chirped frequency as the measurement light.

Return light of the measurement light from the measurement target may be received by the photoelectric conversion element via a plurality of lenses.

The photoelectric conversion element may be made of a material that absorbs light emitted from the diffraction grating.

The photoelectric conversion element may include at least one of germanium (Ge), silicon germanium (SiGe), indium gallium arsenide (InGaAs), gain (GaInAsP), erbium-doped gallium arsenide (GaAs:Er), erbium-doped indium arsenide (InP:Er), carbon-doped silicon (Si: C), gallium antimonide (GaSb), indium arsenide (InAs), indium arsenide antimony phosphorus (InAsSbP), and gallium oxide (Ga₂O₃).

The photodetection element may further include a readout circuit unit configured to convert an output signal of the photoelectric conversion element into a digital signal, in which the photodetection element may have a stacked structure in which the light emitting unit, the photodetection element, and the readout circuit unit are stacked in this order.

The readout circuit unit may be configured on a silicon-on-insulator (SOI) substrate having a structure including silicon oxide (SiO₂) between a silicon (Si) substrate and a silicon (Si) layer as a surface layer.

The readout circuit unit may be electrically connected to a detection circuit board.

The readout circuit unit may be electrically connected to a detection element that detects visible light.

The photoelectric conversion element may include a balanced photodiode.

A lens may be formed on the photoelectric conversion element.

One or more lenses may be arranged for one photodetection element.

A curved surface lens having an uneven structure may be formed on the photoelectric conversion element.

A metalens may be formed on the photoelectric conversion element.

A plurality of the photoelectric conversion elements may be arranged in a two-dimensional lattice pattern.

The light detection element may further include a readout circuit unit configured to convert an output signal of the photoelectric conversion element into a digital signal, in which the readout circuit unit may include:
a trans-impedance amplifier configured to amplify an output signal of the photoelectric conversion element; and
an analog-to-digital converter configured to convert an output signal of the trans-impedance amplifier into a digital signal.

The trans-impedance amplifier and the analog-to-digital converter may be arranged for each of the photoelectric conversion elements.

One trans-impedance amplifier may be disposed for each of the plurality of photoelectric conversion elements.

One analog-to-digital converter may be arranged for each of the plurality of photoelectric conversion elements.

The light emitting unit, the photoelectric conversion element, and the readout circuit unit may be stacked in this order.

The light emitting unit corresponds to the photoelectric conversion element, and at least one light emitting unit may be arranged for one photoelectric conversion element.

The light emitting unit may correspond to a plurality of the photoelectric conversion elements, and at least one row of the light emitting unit may be arranged for the plurality of photoelectric conversion elements.

The light emitting unit, the photoelectric conversion element, and the readout circuit unit may be configured on a silicon-on-insulator (SOI) substrate.

The light emitting unit, the photoelectric conversion element, and the readout circuit unit may be connected by metal wiring.

The photodetection element may further include a second photoelectric conversion element configured to detect visible light, in which the second photoelectric conversion element may be disposed on a light incident side with respect to the photoelectric conversion element.

A photodetection device may include:
the photodetection element; and
a light source of the measurement light.

A plurality of the photoelectric conversion elements may be arranged in a two-dimensional lattice pattern, and
the light emitting units may be arranged corresponding to the plurality of photoelectric conversion elements arranged in the lattice pattern.

The photodetection device may further include a control unit that is disposed corresponding to the photoelectric conversion element and is configured to control light emission of the light emitting unit.

The control unit may perform control to cause the light emitting units corresponding to the plurality of the photoelectric conversion elements so as to emit light at the same timing.

The control unit may control the light emitting units corresponding to the plurality of the photoelectric conversion elements arranged in rows so as to change rows while emitting light.

The control unit may control the light emitting units corresponding to the plurality of the photoelectric conversion elements arranged in a plurality of rows so as to change rows while emitting light.

The control unit may cause the light emitting units corresponding to the plurality of the photoelectric conversion elements to emit light, and may further convert output signals of some of the photoelectric conversion elements among the plurality of photoelectric conversion elements into digital signals.

According to the present disclosure, there is provided a photodetection element including:
a first photoelectric conversion element configured to detect infrared light; and
a second photoelectric conversion element configured to detect visible light,
in which the second photoelectric conversion element is disposed on a light incident side with respect to the first photoelectric conversion element.

The photodetection element may further include a third photoelectric conversion element configured to detect infrared light in a wavelength band different from a wavelength band of the first photoelectric conversion element.

The third photoelectric conversion element and the second photoelectric conversion element may be stacked.

The photodetection element may further include a two-dimensional array-like optical diffraction structure portion having an inverse pyramid shape, in which the optical diffraction structure portion is disposed on a light incident side of the second photoelectric conversion element.

### BRIEF DESCRIPTION OF DRAWINGS

FIG. 1 is a schematic configuration diagram showing an example of a configuration of a photodetection device to which a photodetection element according to a first embodiment of the present disclosure is applied.

FIG. 2 is a diagram showing an example of a configuration of the photodetection element.

FIG. 3 is a diagram showing a configuration example of a pixel array unit and an optical modulation unit of the photodetection element.

FIG. 4 is a diagram showing Configuration Example 1 of a pixel.

FIG. 5 is a diagram showing exemplary signals in the pixel.

FIG. 6 is a diagram showing an example of a signal processing result of a signal processing unit.

FIG. 7 is a cross-sectional view of the pixel.

FIG. 8 is a diagram showing a configuration example of the photodetection element in which the pixels shown in FIG. 7 are arranged.

FIG. 9 is a diagram showing another configuration example of the photodetection element in which the pixels shown in FIG. 7 are arranged.

FIG. 10 is a diagram showing a configuration example of the plurality of pixels arranged in the same row.

FIG. 11 is a diagram showing characteristic parameters when a light emitting unit is configured by a diffraction grating.

FIG. 12 is a diagram showing a simulation result example for the characteristic parameters shown in FIG. 11.

FIG. 13 is a cross-sectional view of a pixel in a case where a microlens is not arranged.

FIG. 14 is a cross-sectional view of a pixel in which an optical circuit unit and a readout circuit unit are stacked.

FIG. 15 is a cross-sectional view of a pixel in which the pixel and the microlens in FIG. 14 are stacked.

FIG. 16 is a cross-sectional view of a pixel in which a readout circuit unit is arranged below the pixel in FIG. 13.

FIG. 17 is a cross-sectional view of a pixel in which a microlens is arranged in the pixel in FIG. 16.

FIG. 18 is a cross-sectional view of a pixel in which a microlens is arranged only on a photoelectric conversion element side of the pixel in FIG. 16.

FIG. 19 is a diagram showing a configuration example of a microlens.

FIG. 20 is a diagram showing an example of a method of manufacturing a microlens.

FIG. 21 is a diagram showing a configuration example of a microlens configured by a metalens.

FIG. 22 is a diagram showing an example of a method of manufacturing the microlens configured by the metalens.

FIG. 23 is a diagram schematically showing a configuration example of one row of the pixel array unit.

FIG. 24 is a diagram showing an example in which a grating portion is also formed on an emission side of reference light of a light irradiation unit.

FIG. 25 is a diagram showing an example in which the light irradiation unit is formed by a micro electro mechanical system (MEMS).

FIG. 26 is a diagram showing an example in which the light irradiation unit has a photonics structure.

FIG. 27 is a diagram showing a configuration example of pixels showing two adjacent pixels in one row.

FIG. 28 is a diagram showing Configuration Example 2 of the pixel.

FIG. 29 is a diagram showing Configuration Example 3 of the pixel.

FIG. 30 is a diagram showing Configuration Example 4 of the pixel.

FIG. 31 is a diagram showing a relationship between a transmission wave signal and a reflection wave signal.

FIG. 32 is a diagram showing a relationship between reference light and return light.

FIG. 33 is a diagram showing a beat frequency calculated by a processing unit.

FIG. 34 is a diagram showing a control example of the entire surface irradiation of the pixel array unit 2.

FIG. 35 is a diagram showing an example in which the light irradiation unit in the first row indicated by the arrow emits light.

FIG. 36 is a diagram showing an example in which the light irradiation unit in the second row indicated by the arrow emits light.

FIG. 37 is a diagram showing an example in which the light irradiation unit in the third row indicated by the arrow emits light.

FIG. 38 is a diagram showing an example in which the light irradiation units in the first and second rows indicated by the arrows emit light.

FIG. 39 is a diagram showing an example in which the light irradiation units in the third and fourth rows indicated by the arrows emit light.

FIG. 40 is a diagram showing an example in which the light irradiation units in the fifth and sixth rows indicated by the arrows emit light.

FIG. 41 is a diagram showing an example in which the light irradiation units in the first to third rows indicated by the arrows emit light.

FIG. 42 is a diagram showing an example in which the light irradiation units in the second to fourth rows indicated by the arrows emit light.

FIG. 43 is a diagram showing an example in which the light irradiation units in the third to fifth rows indicated by the arrows emit light.

FIG. 44 is a diagram showing a configuration example of the pixel 2 corresponding to FIG. 10.

FIG. 45 is a diagram showing Configuration Example 3 of a plurality of pixels.

FIG. 46 is a diagram showing a configuration example of the pixel corresponding to FIG. 45.

FIG. 47 is a diagram showing Configuration Example 4 of the plurality of pixels.

FIG. 48 is a diagram showing a configuration example of the pixel corresponding to FIG. 47.

FIG. 49 is a diagram showing Configuration Example 5 of the plurality of pixels.

FIG. 50 is a diagram showing a configuration example of the pixel corresponding to FIG. 49.

FIG. 51 is a diagram showing Configuration Example 6 of the plurality of pixels.

FIG. 52 is a diagram showing a configuration example of the pixel corresponding to FIG. 51.

FIG. 53 is a diagram showing Configuration Example 7 of the plurality of pixels.

FIG. 54 is a diagram showing a configuration example of the pixel corresponding to FIG. 53.

FIG. 55 is a diagram showing Configuration Example 2 of the pixel in which an analog-to-digital conversion circuit is shared by pixels in a column direction.

FIG. 56 is a diagram showing Configuration Example 3 of the pixel in which the analog-to-digital conversion circuit is shared by pixels in the column direction.

FIG. 57 is a diagram showing Configuration Example 8 of the plurality of pixels.

FIG. 58 is a diagram showing Configuration Example 9 of the plurality of pixels.

FIG. 59 is a diagram showing a configuration example of the pixel corresponding to FIGS. 57 and 58.

FIG. 60 is a diagram showing Configuration Example 10 of the plurality of pixels.

FIG. 61 is a diagram showing a configuration example of a pixel capable of visible imaging.

FIG. 62 is a cross-sectional view showing a configuration example of a pixel capable of visible imaging.

FIG. 63 is a cross-sectional view of a pixel in which the pixel capable of visible imaging and the pixel capable of infrared imaging are further stacked.

FIG. 64 is a cross-sectional view showing a configuration example of a pixel capable of visible imaging.

FIG. 65 is a cross-sectional view showing a configuration example of a pixel capable of visible imaging.

FIG. 66 is a cross-sectional view of a pixel in which the pixel capable of visible imaging and the pixel capable of infrared imaging are further stacked.

FIG. 67 is a cross-sectional view of a pixel in which the pixel capable of visible imaging and the pixel capable of infrared imaging are further stacked.

FIG. 68 is a cross-sectional view showing a configuration example of a pixel capable of visible imaging.

FIG. 69 is a cross-sectional view of a pixel in which the pixel capable of visible imaging and the pixel capable of infrared imaging are further stacked.

FIG. 70 is a diagram showing a configuration example of a pixel capable of visible imaging.

FIG. 71 is a cross-sectional view of a pixel in which the pixel capable of visible imaging and the pixel capable of infrared imaging are further stacked.

FIG. 72 is a block diagram showing a configuration example of a vehicle control system that is an example of a mobile device control system to which the present technology is applied.

FIG. 73 is a diagram showing examples of sensing regions of a camera, a radar, a LiDAR 53, an ultrasonic sensor, and the like of an external recognition sensor in FIG. 72.

### MODE FOR CARRYING OUT THE INVENTION

Hereinafter, embodiments of the present invention will be described with reference to the drawings. Note that, in the drawings attached to the present specification, for convenience of illustration and ease of understanding, scales, vertical and horizontal dimensional ratios, and the like are appropriately changed and exaggerated from actual ones.

### First Embodiment

### (Configuration of Distance Measuring Device)

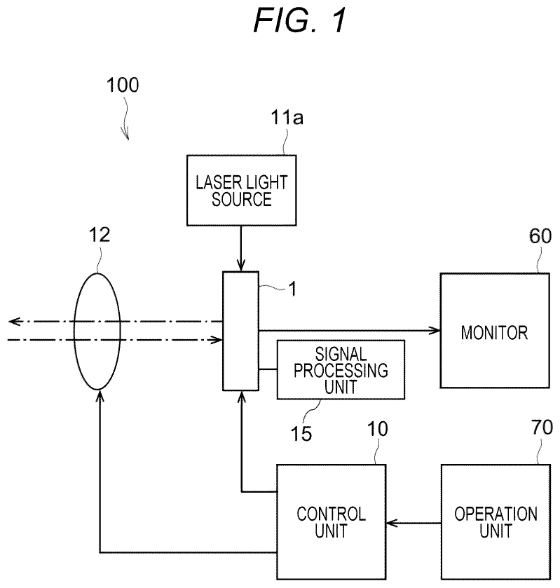

FIG. 1 is a schematic configuration diagram showing an example of a configuration of a photodetection device to which a photodetection element according to a first embodiment of the present disclosure is applied.

A photodetection device 100 according to the first embodiment can be applied to, for example, a photodetection element that measures a distance to an object (subject) on the basis of a light flight time. In addition, the photodetection device 100 can capture an image. As shown in FIG. 1, the photodetection device 100 includes a photodetection element 1, a laser light source 11a, a lens optical system 12, a control unit 10, a signal processing unit 15, a monitor 60, and an operation unit 70. Note that the photodetection device 100 may include at least the photodetection element 1, the laser light source 11a, the control unit 10, the monitor 60, and the operation unit 70. In this case, the lens optical system 12 can be externally connected to the photodetection device 100.

The laser light source 11a generates a laser beam under the control of the control unit 10. A wavelength λ of 700 nm or more is used. As an example, light in an eye safe band that does not affect the eye, such as wavelengths λ of 1550 nm, 1330 nm, and 2000 nm, is used. Further, for example, an AlGaAs-based semiconductor laser may generate laser light having a wavelength λ of 940 nm.

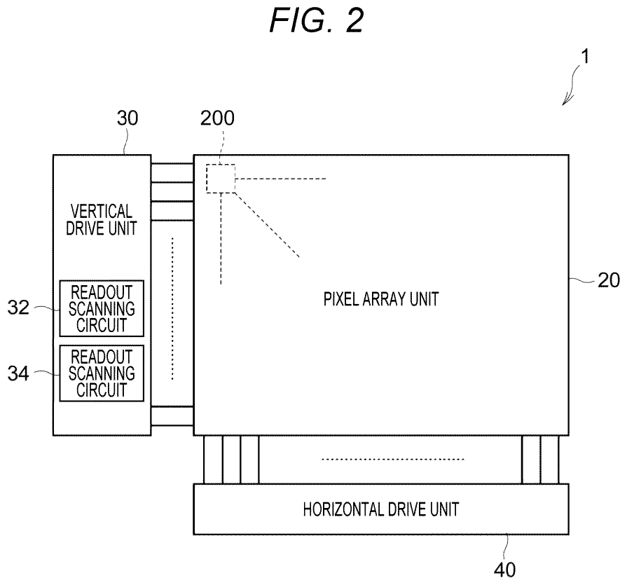

The lens optical system 12 condenses the laser light emitted from the photodetection element 1, sends the condensed laser light to a subject, guides the light from the subject to the photodetection element 1, and forms an image on a pixel array unit 20 (see FIG. 2) of the photodetection element 1.

Also, the lens optical system 12 performs focus adjustment and drive control for the lens, under the control of the control unit 10. Further, the lens optical system 12 sets an aperture to a designated aperture value, under the control of the control unit 10. The signal processing unit 15 performs signal processing such as Fourier transform processing on a signal including distance information generated by the pixel array unit 20 (see FIG. 2), for example. As a result, distance image data including the information regarding the distance value corresponding to each pixel constituting the pixel array unit 20 is generated. Furthermore, the signal processing unit 15 can also process an imaging signal photoelectrically converted by a visible photoelectric conversion element included in the pixel array unit 20 to generate captured image data.

The monitor 60 can display at least one of the distance image data and the captured image data obtained by the photodetection element 1. A user (for example, a photographer) of the photodetection device 100 can observe the image data from the monitor 60. The control unit 10 includes a CPU, a memory, and the like, and controls driving of the photodetection element 1 and controls the lens optical system 12 in response to an operation signal from the operation unit 70.

### (Configuration of Photodetection Device)

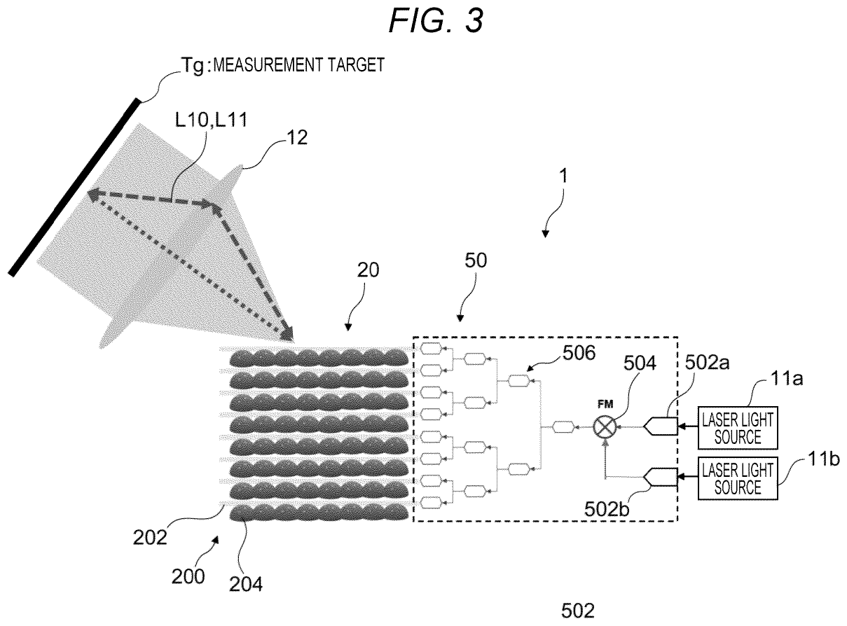

FIG. 2 is a diagram showing an example of a configuration of the photodetection element 1. As shown in the drawing, the photodetection element 1 includes, for example, the pixel array unit 20, a vertical drive unit 30, a horizontal drive unit 40, and an optical modulation unit 50 (see FIG. 3). Operations of the vertical drive unit 30 and the horizontal drive unit 40 are controlled by the control unit 10.

The pixel array unit 20 includes a plurality of pixels 200 that are arranged in an array (a matrix), and generate and accumulate electric charge in accordance with the intensity of incident light. As the arrangement of pixels, a Quad arrangement or a Bayer arrangement is known, for example, but the arrangement is not limited to this. In the drawing, an up-down direction of the pixel array unit 20 is referred to as a column direction or a vertical direction, and a left-right direction is referred to as a row direction or a horizontal direction. Note that details of the configuration of the pixels in the pixel array unit 20 will be described later.

The vertical drive unit 30 includes a shift register and an address decoder (not shown in the drawing). Under the control of the control unit 10, the vertical drive unit 30 sequentially drives, for example, the plurality of pixels 200 of the pixel array unit 20 row by row in the vertical direction, for example. In the present disclosure, the vertical drive unit 30 may include a readout scanning circuit 32 that performs scanning for reading a signal, and a sweep scanning circuit 34 that performs scanning for sweeping (resetting) unnecessary electric charge from photoelectric conversion elements.

The readout scanning circuit 32 sequentially and selectively scans the plurality of pixels 200 of the pixel array unit 20 row by row, to read a signal based on the electric charge from each pixel 200. The sweep scanning circuit 34 performs sweep scanning on a readout row on which a readout operation is to be performed by the readout scanning circuit 32, earlier than the readout operation by the time corresponding to the operation speed of the electronic shutter. A so-called electronic shutter operation can be performed by sweeping (resetting) unnecessary charges by the sweep scanning circuit 34.

The horizontal drive unit 40 includes a shift register and an address decoder (not shown in the drawing). Under the control of the control unit 10, the horizontal drive unit 40 sequentially drives, for example, the plurality of pixels 200 of the pixel array unit 20 column by column in the horizontal direction, for example. A signal based on the charge accumulated in the selected pixel 200 is output to the signal processing unit 15 by selective driving of the pixel by the vertical drive unit 30 and the horizontal drive unit 40.

### (Configuration Example of Pixel Array Unit 20 and Optical Modulation Unit 50)

FIG. 3 is a diagram showing a configuration example of the pixel array unit 20 and the optical modulation unit 50 of the photodetection element 1. As shown in FIG. 3, the pixel array unit 20 includes a plurality of pixels 200 arranged in a two-dimensional matrix. Note that the pixel 200 according to the present embodiment includes a light emitting unit 202 and a microlens 204, but is not limited thereto. For example, as will be described later, a configuration without the microlens 204 is also possible.

The light emitting unit 202 emits light introduced from the optical modulation unit 50. The light emitting unit 202 according to the present embodiment is arranged for each row of the pixel array unit 20, and is continuous from one end to the other end of the pixel array unit 20, for example. As the material of the light emitting unit 202, a material having a band gap equal to or more than energy corresponding to the wavelength of the laser light is used. Examples of the material include silicon (Si), silicon nitride (Si₃N₄), gallium nitrate (Ga₂O₃), and germanium (Ge). Note that the light emitting unit 202 according to the present embodiment is continuous from one end to the other end of the pixel array unit 20, but is not limited thereto. Furthermore, in each pixel 200, the microlens 204 that emits and collects light is arranged. Note that the microlens 204 may be referred to as an on-chip lens (OCL).

The optical modulation unit 50 includes a plurality of light receiving ends 502a and 502b, a frequency modulation unit 504, and an optical switch 506. The plurality of light receiving ends (input ports) 502a and 502b are, for example, spot size converters. The plurality of light receiving ends (input ports) 502a and 502b receive light introduced from the plurality of laser light sources 11a and 11b, and guide laser light to a frequency modulation unit (FM) 504 via a waveguide. The waveguide includes, for example, an optical fiber.

The wavelength of the laser light source 11a is, for example, 1550 nm, and the wavelength of the laser light source 11b is, for example, 1330 nm. As a result, laser light having a wavelength of 1550 nm or 1330 nm is guided to the optical modulation unit 50 under the control of the control unit 10 (see FIG. 1). The optical modulation unit 50 generates a chirp wave in which the frequency of the laser light is increased or decreased in time series. That is, the frequency of the chirp wave increases and decreases in time series. Then, the chirp wave is guided to the light emitting unit 202 of each row via the optical switch 506. Further, the laser light sources 11a and 11b may be configured by light emitting diodes such as LEDs (Light Emitting Diodes).

The optical switch 506 can change a row through which light is transmitted, for example, under the control of the control unit 10 (see FIG. 1). The optical switch 506 can be configured by, for example, a micro electro mechanical system (MEMS) type optical switch.

A measurement target Tg is irradiated with the chirp wave emitted from the light emitting unit 202 of each row for each pixel 200 via the microlens 204 and the lens optical system 12 as measurement light L10. Then, return light L11 reflected by the measurement target Tg is received for each pixel 200 via the lens optical system 12 and the microlens 204. In this case, for example, the measurement target Tg is irradiated with the measurement light L10, and the return light L11 reflected and returned from the measurement target Tg follows the same optical path as the measurement light L10 and is received by the emitted same microlens 204.

### (Configuration Example 1 of Pixel 200)

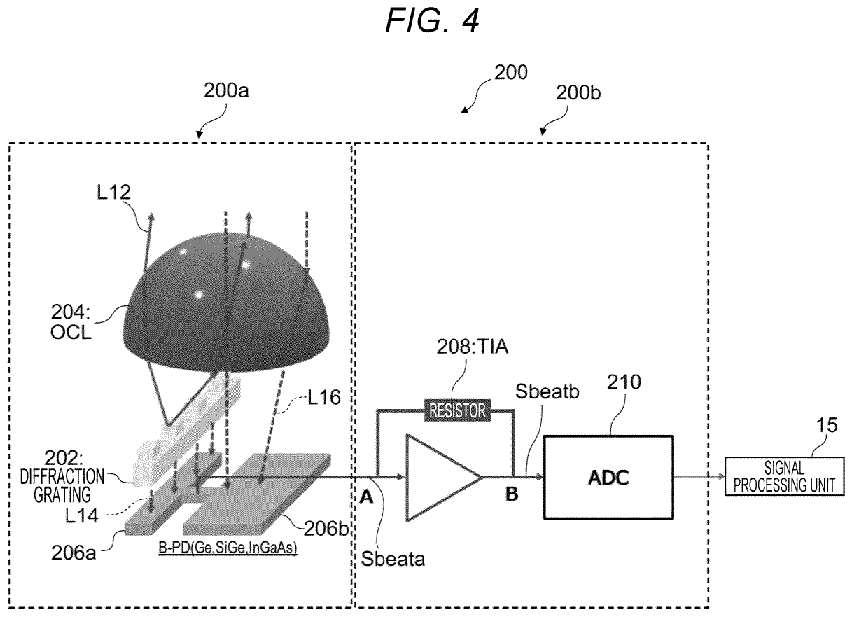

FIG. 4 is a diagram showing Configuration Example 1 of the pixel 200. As shown in FIG. 4, the pixel 200 includes, for example, an optical circuit unit 200a and a readout circuit unit 200b. Note that the pixel 200 according to the present embodiment includes the readout circuit unit 200b, but is not limited thereto. For example, the readout circuit unit 200b may be configured on a common substrate outside the pixel 200.

The optical circuit unit 200a emits measurement light L12, receives reference light L14 and return light L16, and generates a first beat signal Sbaeta. More specifically, the optical circuit unit 200a includes a light emitting unit (diffraction grating) 202, a macrolens (OCL) 204, and photoelectric conversion elements 206a and 206b.

With such a configuration, the light emitting unit 202 emits the measurement light L12 in the first direction. On the other hand, the light emitting unit 202 emits the reference light L14 in a second direction different from the first direction. For example, the second direction is a direction opposite to the first direction. Note that the second direction according to the present embodiment is a direction opposite to the first direction, but is not limited thereto. For example, the second direction may be different from the first direction by, for example, 90 degrees, 120 degrees, or 150 degrees. In this case, the reference light L14 may be received by the photoelectric conversion element 206a by moving the light receiving range of the photoelectric conversion element 206a or reflecting the light on a mirror surface. Note that the reference light L14 may be referred to as leak light, and the return light L16 may be referred to as reflected light.

Further, as shown in FIG. 4, in the light emitting unit 202, a first region emitting the measurement light L12 and a second region emitting the reference light L14 are different. For example, the second region is a region of a surface opposite to the traveling direction of the measurement light L12 emitted from the first region.

The photoelectric conversion elements 206a and 206b are, for example, balanced photodiodes (B-PDs), and include a photoelectric conversion element 206a and a photoelectric conversion element 206b. The photoelectric conversion element 206a and the photoelectric conversion element 206b are configured by a common photoelectric conversion element, the photoelectric conversion element 206a mainly receives the reference light L14, and the photoelectric conversion element 206b mainly receives the return light L16. Note that the photoelectric conversion element 206a may also receive the return light L16, and the photoelectric conversion element 206b may also receive the reference light L14. As can be seen from the above, the reference light L14 and the return light L16 are multiplexed by the photoelectric conversion element 206a and the photoelectric conversion element 206b, and the first beat signal Sbaeta is generated as a frequency modulated continuous wave (FMCW) signal which is a signal after photoelectric conversion by the photoelectric conversion elements 206a and 206b. In addition, the photoelectric conversion elements 206a and 206b include at least one of germanium (Ge), silicon germanium (SiGe), indium gallium arsenide (InGaAs), gain (GaInAsP), erbium-doped gallium arsenide (GaAs:Er), erbium-doped indium arsenide (InP:Er), carbon-doped silicon (Si: C), gallium antimonide (GaSb), indium arsenide (InAs), indium arsenide antimony phosphorus (InAsSbP), and gallium oxide (Ga₂O₃).

In this manner, by emitting the measurement light L12 in the first direction from the light emitting unit 202 and emitting the reference light L14 in the second direction different from the first direction from the light emitting unit 202, the photoelectric conversion elements 206a and 206b can be arranged at positions that do not hinder the emission of the measurement light L12. Furthermore, since the photoelectric conversion elements 206a and 206b directly receive the reference light L14, the photoelectric conversion elements 206a and 206b can multiplex the reference light L14 and the return light L16 without using an optical fiber for multiplexing, an optical coupler, or the like. Therefore, the pixel 200 can be downsized. As a result, the photodetection element 1 and the photodetection device 100 can be further downsized.

The readout circuit unit 200b amplifies the first beat signal (Sbeata) generated by the photoelectric conversion elements 206a and 206b and converts the first beat signal into a digital signal. More specifically, a trans-impedance amplifier (TIA) 208 and an analog-to-digital conversion circuit (ADC) 210 are included. That is, the trans-impedance amplifier 208 amplifies the first beat signal (Sbeata) generated by the photoelectric conversion elements 206a and 206b to generate a second beat signal (Sbeatb). Then, the analog-to-digital conversion circuit 210 converts the second beat signal (Sbeatb) into a digital signal and outputs the digital signal to the signal processing unit 15.

### (Signal Characteristics)

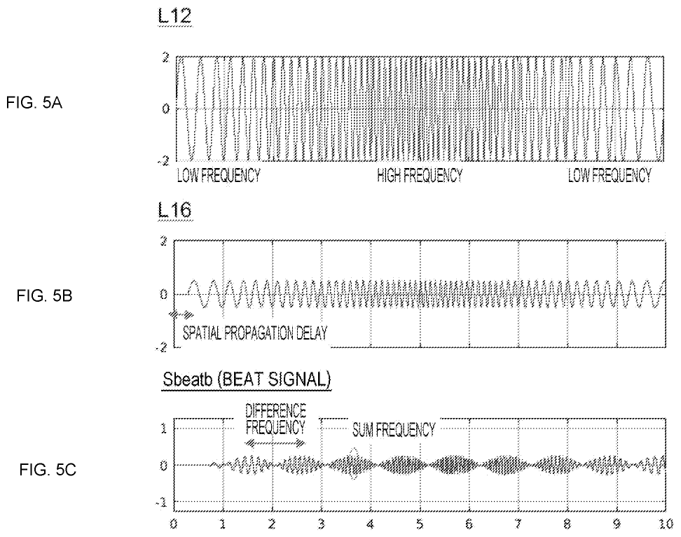

FIG. 5 is a diagram showing exemplary signals in the pixel 200. FIG. 5A is a graph showing a frequency change of the light intensity of the reference light L14. The horizontal axis represents time, and the vertical axis represents light intensity (power). As shown in FIG. 5A, the reference light L14 is a chirp wave whose frequency increases and decreases in time series. The measurement light L12 also has a different light intensity, but is a chirp wave equivalent to that of the reference light L14.

FIG. 5B is a graph showing conversion of the light intensity of the return light L16. The horizontal axis represents time, and the vertical axis represents light intensity (power). As shown in FIG. 5B, the frequency of the return light L16 increases or decreases in time series with a delay of spatial propagation.

FIG. 5C is a graph showing a change in the light intensity of the first beat signal (Sbeata). The horizontal axis represents time, and the vertical axis represents light intensity (power). As shown in FIG. 5C, the first beat signal (Sbeata) becomes a beat signal having information regarding a delay of spatial propagation by multiplexing of the reference light L14 and the return light L16. The first beat signal (Sbeata) generates a beat frequency.

### (Example of Signal Processing Result)

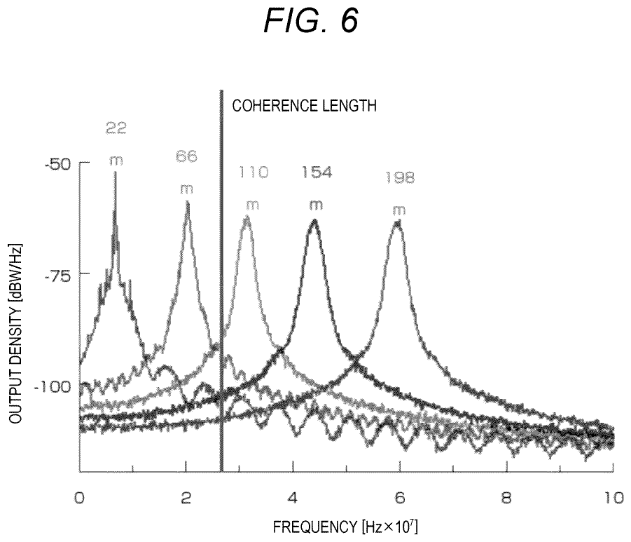

FIG. 6 is a diagram showing an example of a signal processing result of the signal processing unit 15. The horizontal axis represents the beat frequency, and the vertical axis represents the power density. As shown in FIG. 6, the signal processing unit 15 (see FIG. 1) uses the fact that the frequency of the first beat signal (Sbeata) amplified and digitally converted changes depending on the distance, and performs distance measurement by heterodyne detection, for example. That is, the signal processing unit 15 performs Fourier transform or the like on the digitally converted second beat signal (Sbeatb) to generate distance values 22, 66, 110, 154, 198 meters or the like to the measurement target Tg. Furthermore, the signal processing unit 15 can also generate the Z-direction velocity of the measurement target Tg using the fact that the difference between the two beat frequencies F is a frequency shifted by the Doppler effect.

### (Stacked Structure Example 1 of Pixel 200)

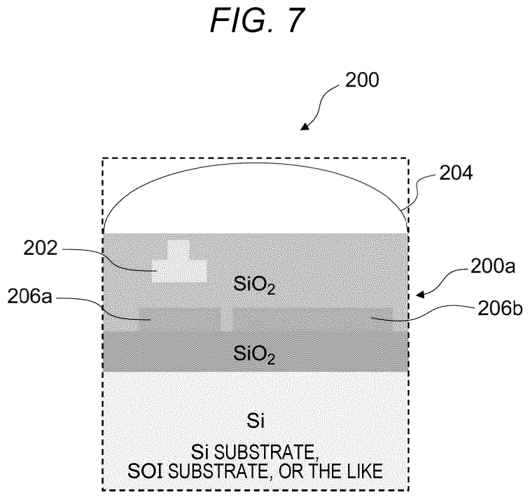

FIG. 7 is a cross-sectional view of the pixel 200. As shown in FIG. 7, the optical circuit unit 200a of the pixel 200 is configured on, for example, a silicon-on-insulator (SOI) substrate having a structure including a silicon (Si) substrate and silicon oxide (SiO₂). Note that the silicon (Si) substrate may be further configured as a silicon-on-insulator (SOI) substrate. As shown in FIG. 7, the photoelectric conversion element 206a is disposed below the light emitting unit 202. On the other hand, since the light emitting unit 202 is not disposed on the photoelectric conversion element 206b, the photoelectric conversion element 206b can receive the return light without being blocked by the light emitting unit 202.

### (Configuration Example 1 of Photodetection Element 1)

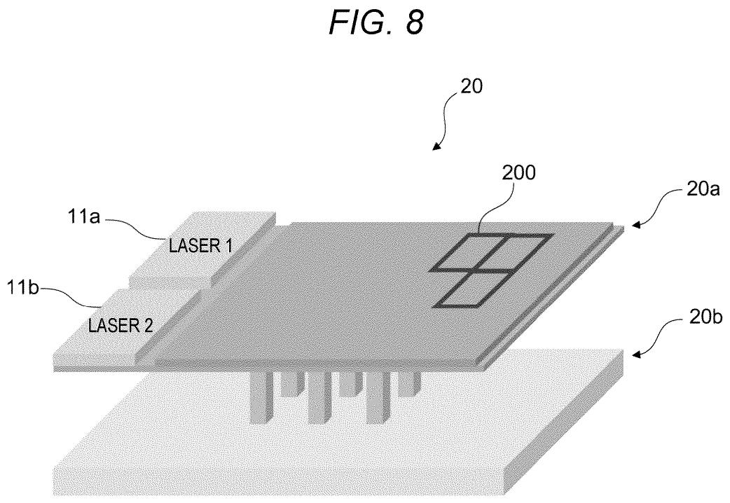

FIG. 8 is a diagram showing a configuration example of the photodetection element 1 in which the pixels 200 shown in FIG. 7 are arranged. The configuration example is formed by a stacked structure by a connection technique such as through silicon via (TSV) or Cu—Cu connection (CCC). For example, the optical circuit unit 200a is configured on an optical circuit unit substrate 20a, and the readout circuit unit 200b is configured on a readout circuit substrate 20b called a read-out integrated circuits (ROIC). As described above, the optical circuit unit substrate 20a and the readout circuit substrate 20b are stacked by a connection technique such as through silicon via (TSV) or Cu—Cu connection (CCC). Further, the laser light source 11a and the laser light source 11b are also configured on a common substrate on which the optical circuit unit substrate 20a is formed.

### (Configuration Example 2 of Photodetection Element 1)

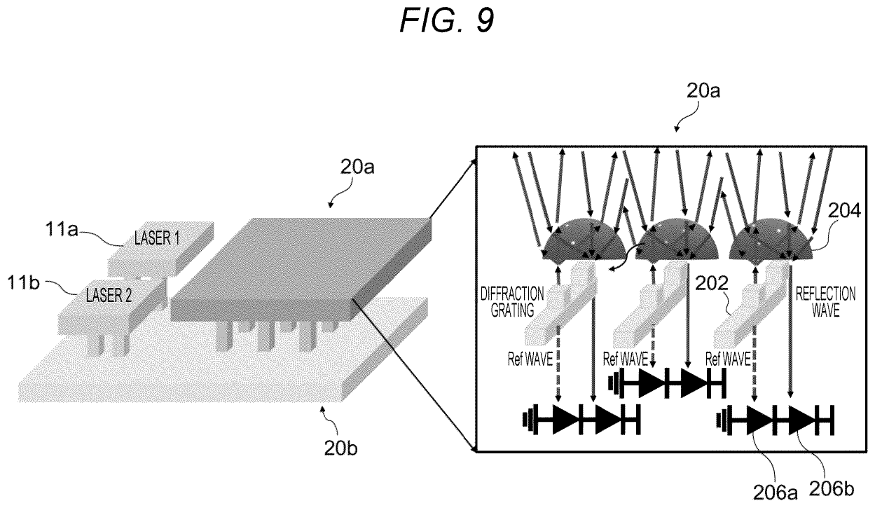

FIG. 9 is a diagram showing another configuration example of the photodetection element 1 in which the pixels 200 shown in FIG. 7 are arranged. The optical circuit unit substrate 20a and the readout circuit substrate 20b are stacked by a connection technique such as through silicon via (TSV) or Cu—Cu connection (CCC). On the other hand, the laser light source 11a and the laser light source 11b are configured separately on a substrate different from the common substrate on which the optical circuit unit substrate 20a is configured. The right diagram is a diagram schematically showing the arrangement of the light emitting unit 202, the microlens 204, and the photoelectric conversion elements 206a and b arranged on the end surface of the optical circuit unit substrate 20a opposite to the laser light source 11a and the laser light source 11b. In this manner, the light emitting units 202 are arranged in parallel along the row direction (horizontal direction).

### (Configuration Example 1 of Plurality of Pixels 200)

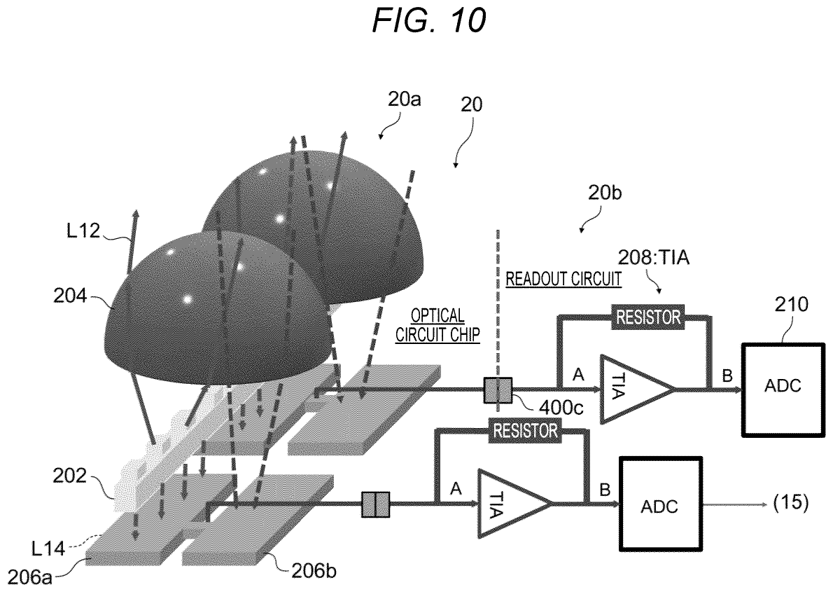

FIG. 10 is a diagram showing a configuration example of the plurality of pixels 200 arranged in the same row. The optical circuit unit substrate 20a and the readout circuit substrate 20b are connected by Cu—Cu connection 400c. As a result, light can be emitted for each row of the pixel array unit 20.

### (Optical Characteristics of Light Emitting Unit 202)

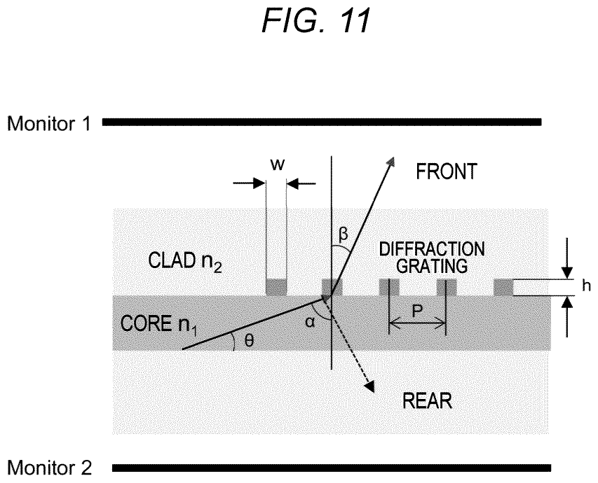

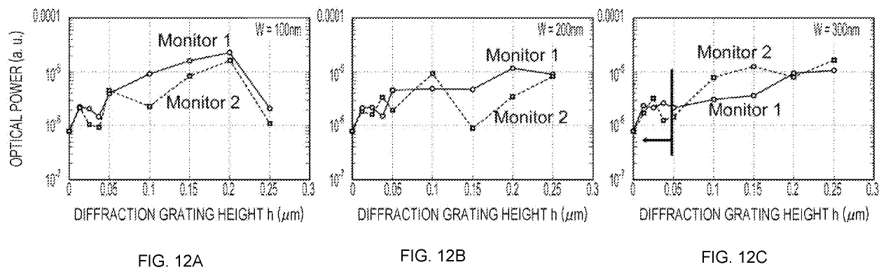

Here, the optical characteristics of the light emitting unit 202 will be described with reference to FIGS. 11 and 12. FIG. 11 is a diagram showing characteristic parameters when the light emitting unit 202 is configured by a diffraction grating. FIG. 12 is a diagram showing a simulation result example for the characteristic parameters shown in FIG. 11. As shown in FIG. 11, a diffraction grating (pitch P, height h, width W) includes a waveguide (core, refractive index n1) that is a main optical path through which light travels, and a grating portion constituting the diffraction grating. The optical characteristics of the diffraction grating vary depending on parameters such as the refractive index n1 of the waveguide (core) and the grating portion, a refractive index n2 of the clad covering the waveguide (core) and the grating portion, the height h, the width W, and the pitch (interval) P of the grating portion.

In A to C of FIG. 12, the horizontal axis represents the height of the grating portion, and the vertical axis represents the power (intensity) of the emitted light. In A of FIG. 12, the width W of the grating portion is 100 micrometers, in B of FIG. 12, the width W of the grating portion is 200 micrometers, and in C of FIG. 12, the width W of the grating portion is 300 micrometers. The power of the light emitted from the front, which is the side where the grating portion is present, is indicated by Monitor 1, and the power of the light emitted from the rear is indicated by Monitor 2. In A of FIG. 12, as the height h increases from 0.05 micrometers to 0.2 micrometers, both the power Monitor 1 on the front side and the power Monitor 2 on the rear side increase and then decrease.

Further, in Fig. B of FIG. 12, the power Monitor 1 on the front side increases or is maintained as the height h increases from 0.05 micrometers to 0.25 micrometers. On the other hand, the power Monitor 2 on the rear side increases as the height h increases from 0.05 micrometers to 0.25 micrometers, then decreases once, and then increases again.

Further, in Fig. C of FIG. 12, both the power Monitor 1 on the front side and the power Monitor 2 on the rear side linearly increase as the height h increases in a range excluding the height h of 0.05 micrometers. In this manner, it is possible to set the shape of the light emitting unit 202 according to the characteristics of the optical system (microlens 204 and optical system 12) and the refractive index n2 of the clad.

### (Stacked Structure Example 2 of Pixel 200)

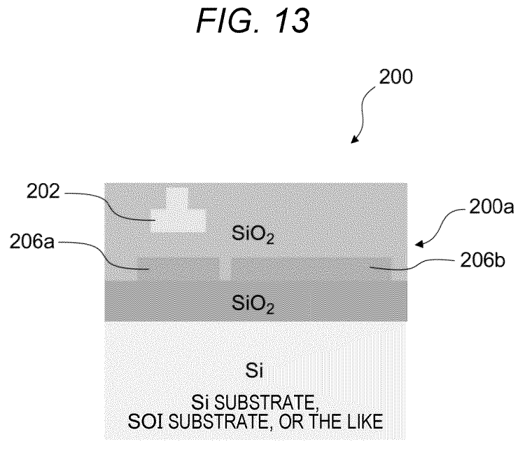

FIG. 13 is a cross-sectional view of a pixel 200 in a case where the microlens 204 is not arranged. As shown in FIG. 13, in a case where the shape of the light emitting unit 202 is set according to the characteristics of the optical system 12 and the refractive index n2 of the clad, according to the structure of the pixel 200, there is a case where the performance condition of light detection is satisfied even in a case where the microlens 204 is not arranged. As described above, the light emitting unit 202 can be designed to have light condensing characteristics or diffusion characteristics similar to those of the microlens 204.

### (Stacked Structure Example 3 of Pixel 200)

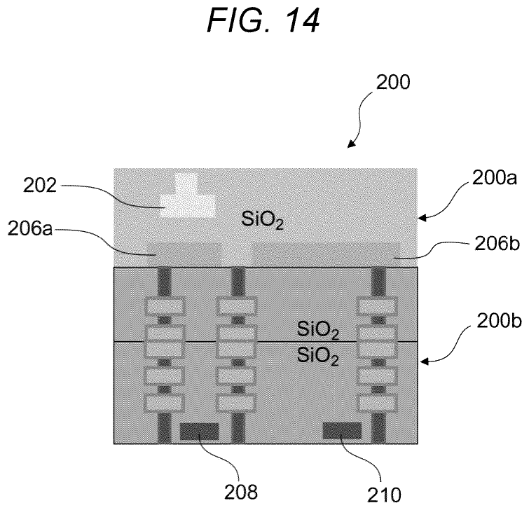

FIG. 14 is a cross-sectional view of a pixel 200 in which the optical circuit unit 200a and the readout circuit unit 200b are stacked. As shown in FIG. 14, the readout circuit unit 200b may be stacked with the optical circuit unit 200a. For example, the readout circuit unit 200b is configured on a silicon oxide (SiO₂) layer. In this case, a silicon oxide (SiO₂) layer may be stacked on a silicon-on-insulator (SOI) substrate or a silicon (Si) substrate. In such a stacked structure, the optical circuit unit 200a and the readout circuit unit 200b can be stacked by connecting copper (Cu) wires to each other or connecting them by a through silicon via TSV or the like.

### (Stacked Structure Example 4 of Pixel 200)

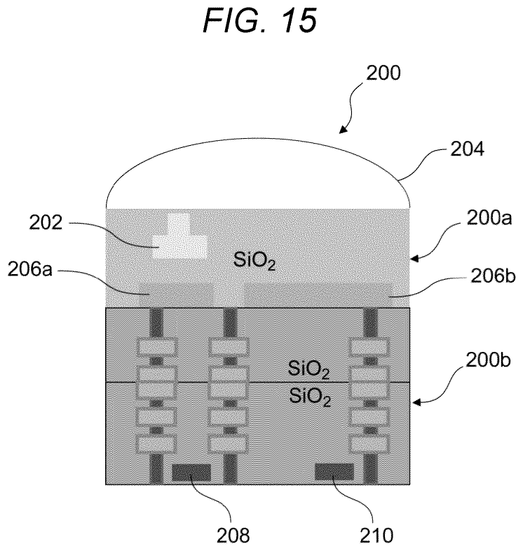

FIG. 15 is a cross-sectional view of a pixel in which the pixel 200 and the microlens 204 in FIG. 14 are stacked. As shown in FIG. 15, this is an example in which the microlens 204 is stacked on the pixel 200 shown in FIG. 14, and the microlens 204 and the light emitting unit 202 are combined. As described above, the optical characteristics of the optical system can be adjusted by combining the microlens 204 and the light emitting unit 202.

### (Stacked Structure Example 5 of Pixel 200)

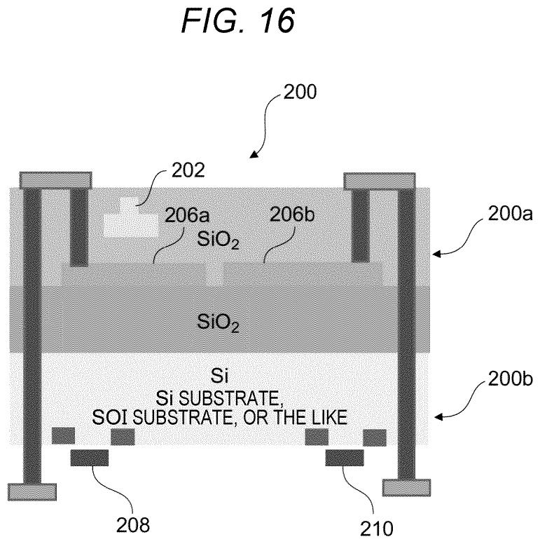

FIG. 16 is a cross-sectional view of a pixel in which the readout circuit unit 200b is arranged below the pixel in FIG. 13. As shown in FIG. 16, since the photoelectric conversion elements 206a and 206b and the readout circuit unit 200b can be electrically connected using through silicon via (TSV) or the like, the device structure can be simplified.

### (Stacked Structure Example 6 of Pixel 200)

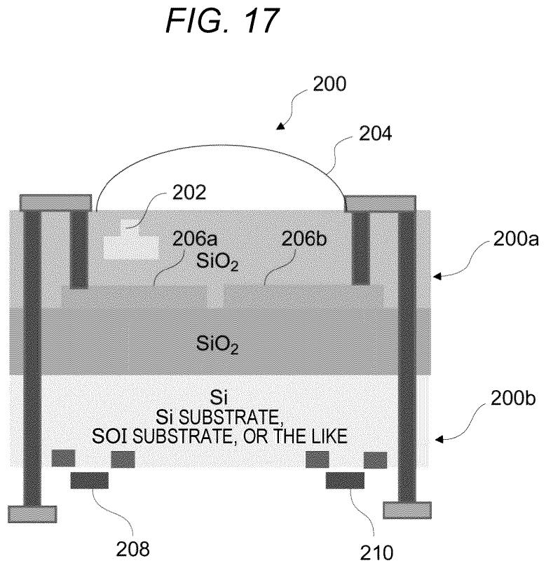

FIG. 17 is a cross-sectional view of a pixel in which a microlens 204a is arranged in the pixel in FIG. 16. As shown in FIG. 17, this is an example in which the microlens 204 is stacked on the pixel 200 shown in FIG. 16, and the microlens 204 and the light emitting unit 202 are combined. As described above, the optical characteristics of the optical system can be adjusted by combining the microlens 204 and the light emitting unit 202.

### (Stacked Structure Example 7 of Pixel 200)

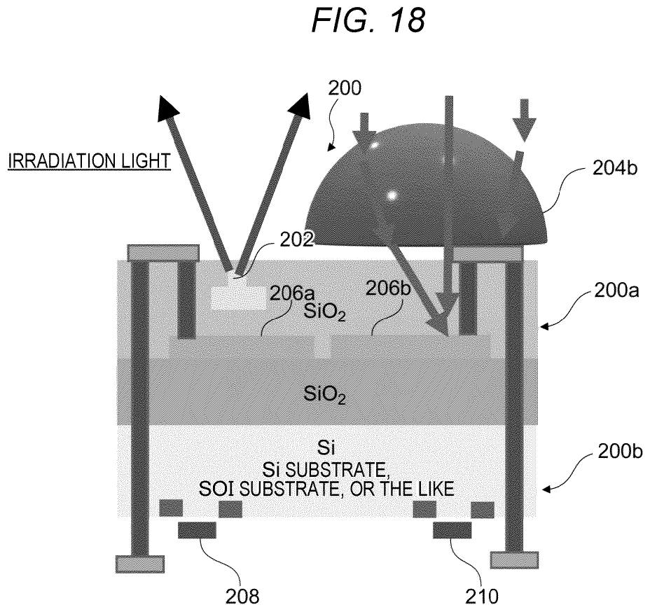

FIG. 18 is a cross-sectional view of a pixel in which a microlens 204b is arranged only on the photoelectric conversion element 206b side of the pixel in FIG. 16. As shown in FIG. 18, it is also possible to stack the microlens 204b only on the photoelectric conversion element 206b side and change the optical characteristics on the emission side (irradiation light) and the return light side of the measurement light. Thus, the position of the microlens 204b can be optimized. In addition, since the light from the light emitting unit 202 is not transmitted through the microlens 204b, light can be emitted at a wider angle. On the other hand, on the photoelectric conversion element 206b side, the return light can be efficiently condensed by the microlens 204b. Furthermore, pupil correction may be performed on the position of the microlens 204b similarly to general imaging.

### (Configuration Example 1 of Microlens)

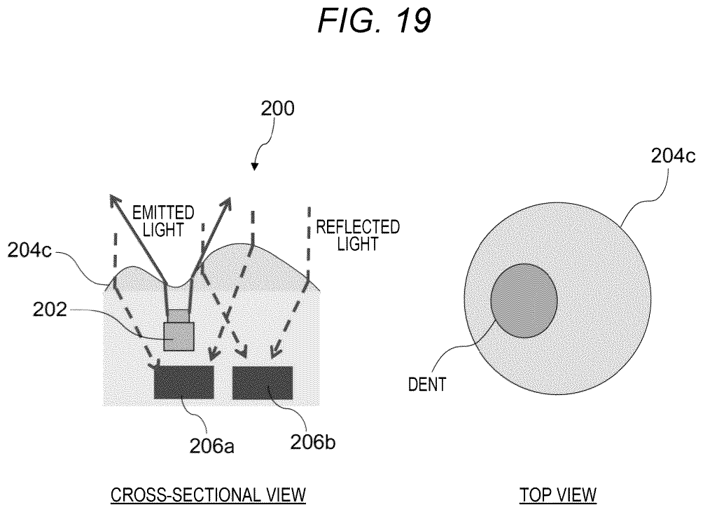

FIG. 19 is a diagram showing a configuration example of a microlens 204c, and shown a cross-sectional view and a top view. The microlens 204c has a curved lens structure. That is, in the microlens 204c, the light emitting unit 202 side is formed as a concave lens, and the photoelectric conversion element 206b side is formed as a convex lens. In this manner, lens characteristics having different optical characteristics can be provided on the emission side (irradiation light) and the return light side of the measurement light.

### (Example 1 of Method of Manufacturing Microlens)

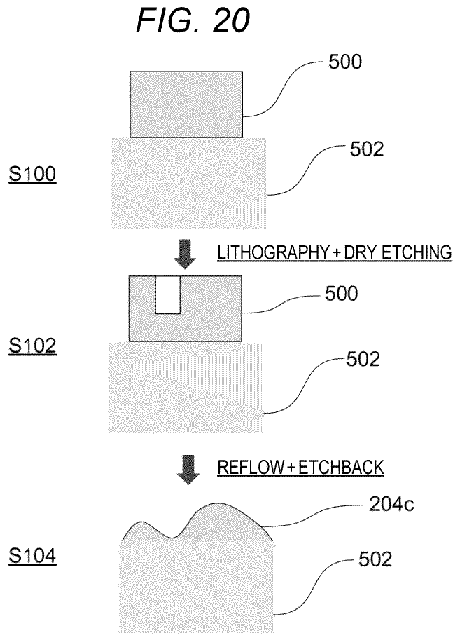

FIG. 20 is a diagram showing an example of a method of manufacturing the microlens 204c. First, a glass material 500 is disposed on a silicon oxide (SiO₂) layer 502 constituting the optical circuit unit 200a (S100). Next, a recessed upper portion is formed on the glass material 500 by dry etching or the like by a lithography technique (S102). Then, a gentle curved surface of the microlens 204c is formed by reflowing (S104).

### (Configuration Example 2 of Microlens)

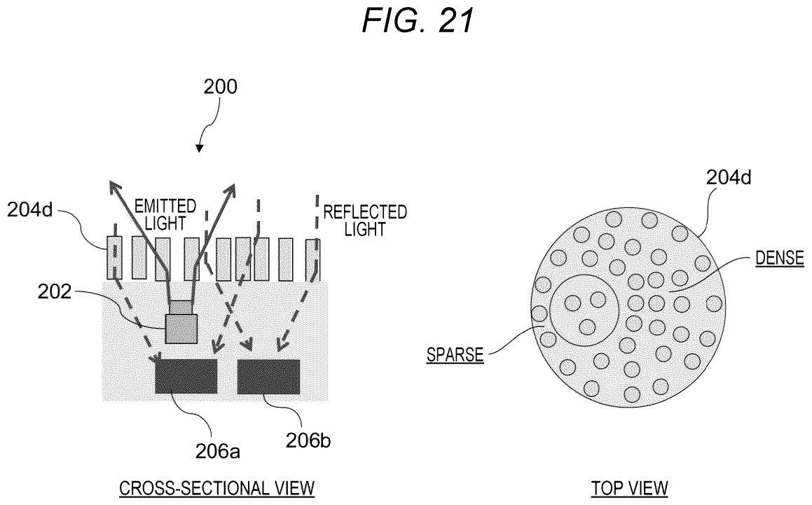

FIG. 21 is a diagram showing a configuration example of a microlens 204d configured by a metalens, and shown a cross-sectional view and a top view. The microlens 204d is formed of a metalens. That is, a concave metalens by the metalens is formed immediately above the light emitting unit 202, and the emitted light is diffused. On the other hand, a convex metalens by a metalens is formed immediately above the photoelectric conversion element 206b, and the return light is condensed. That is, the concave metalens has a sparse columnar arrangement, and the convex metalens has a dense columnar arrangement. As described above, in the microlens 204d, the light emitting unit 202 side is formed as a concave lens, and the photoelectric conversion element 206b side is formed as a convex lens. As a result, lens characteristics having different optical characteristics can be provided on the emission side and the return light side of the measurement light.

### (Example 2 of Method of Manufacturing On-Chip Lens)

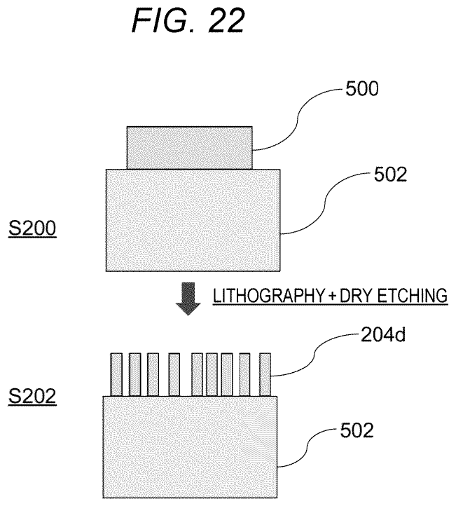

FIG. 22 is a diagram showing an example of a method of manufacturing the microlens 204d configured by the metalens. First, the glass material 500 is disposed on the silicon oxide (SiO₂) layer 502 constituting the optical circuit unit 200a (S200). Next, density is patterned by lithography, and the glass material 500 is dry-etched to form the microlens 204d (S202). The material of the metalens (Piller) portion is made of a material having a higher refractive index. Examples thereof include Si₃N₄, TiO₂, Poly-Silicon, Amorphous-Silicon, TaOx, and Al₂O₃. On the other hand, the material between the Piller-like metalenses is made of a material having a lower refractive index. For example, air, SiO₂, and the like.

### (Configuration Example 1 of One Row of Pixel Array Unit 20)

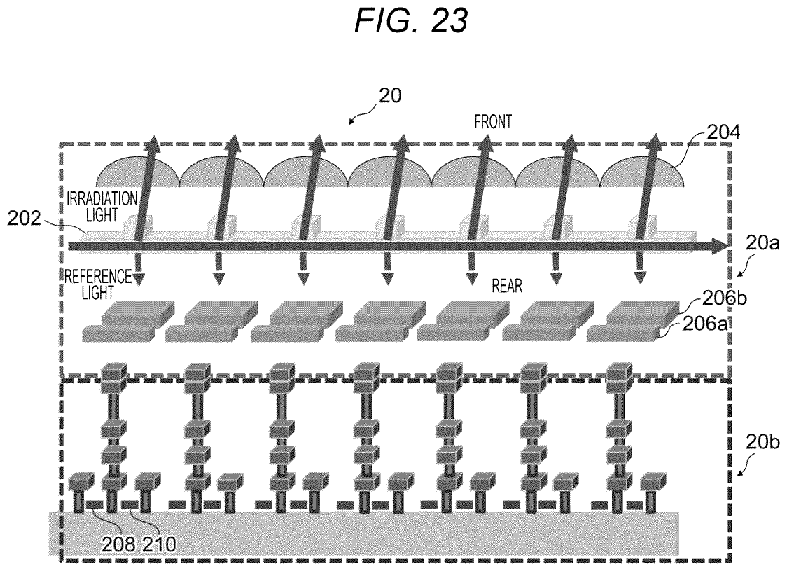

FIG. 23 is a diagram schematically showing a configuration example of one row of the pixel array unit 20. In FIG. 23, as described above, the light emitting unit 202 is an example in which the diffraction grating is formed on the side irradiated with the measurement light (irradiation light) and the diffraction grating is not formed on the emission side of the reference light. As described above, the adjustment of the light intensity and the irradiation angle of the measurement light and the reference light can be made different depending on the presence or absence of the diffraction grating.

### (Configuration Example 2 of One Row of Pixel Array Unit 20)

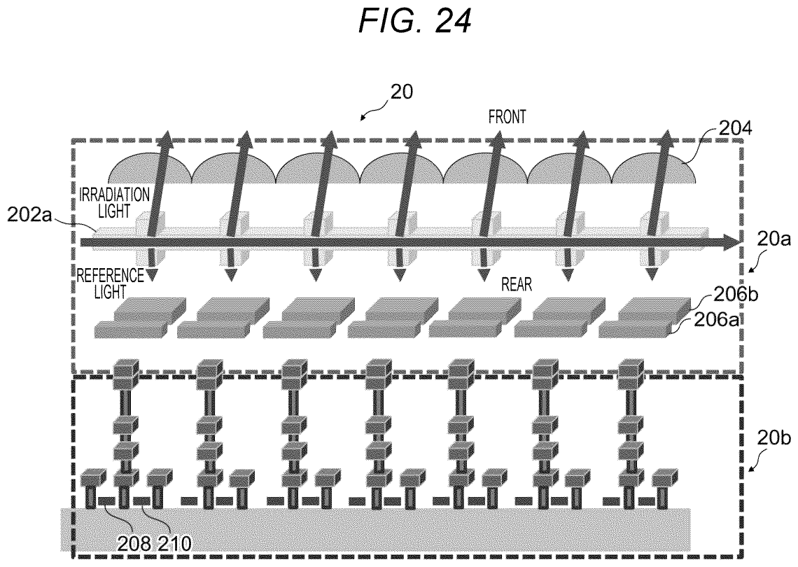

FIG. 24 is a diagram showing an example in which a diffraction grating is also formed on the emission side of the reference light of the light emitting unit 202a. As shown in FIG. 24, a diffraction grating is also formed on the emission side of the reference light of the light emitting unit 202a. This makes it possible to improve the optical power of the reference light. As a result, the measurement accuracy can be further improved by increasing the intensity of the reference light.

### (Configuration Example 3 of One Row of Pixel Array Unit 20)

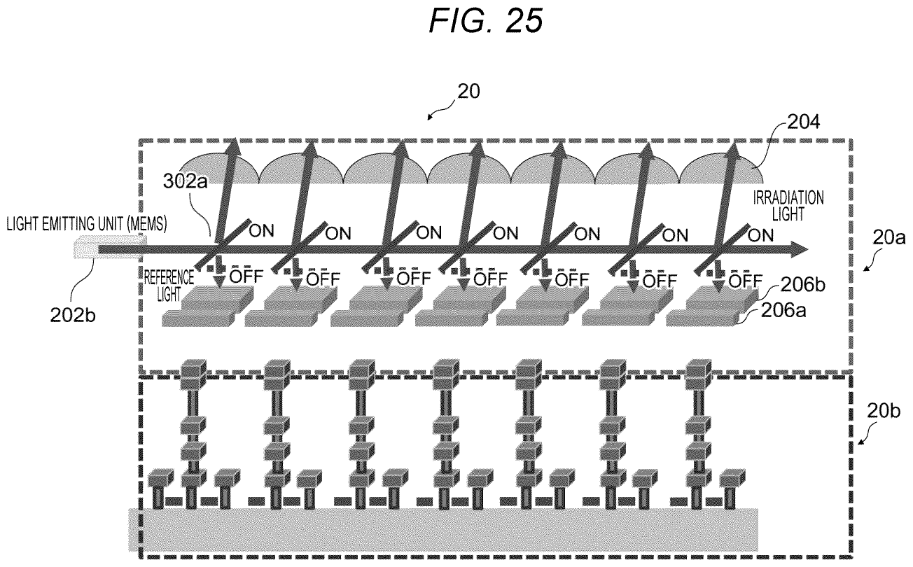

FIG. 25 is a diagram showing an example in which an optical switch is formed by a micro electro mechanical system (MEMS) of a light emitting unit 202b. As shown in FIG. 25, the incident light to the light emitting unit 202b is reflected and diffracted in the upward direction or the downward direction by ON/OFF control of the micro electro mechanical system of the control unit 10. As a result, the light reflected and diffracted in the upward direction becomes measurement light, and the light reflected and diffracted in the downward direction becomes reference light. In this manner, the light emitting unit 202b may be configured by the micro electro mechanical system.

### (Configuration Example 4 of One Row of Pixel Array Unit 20)

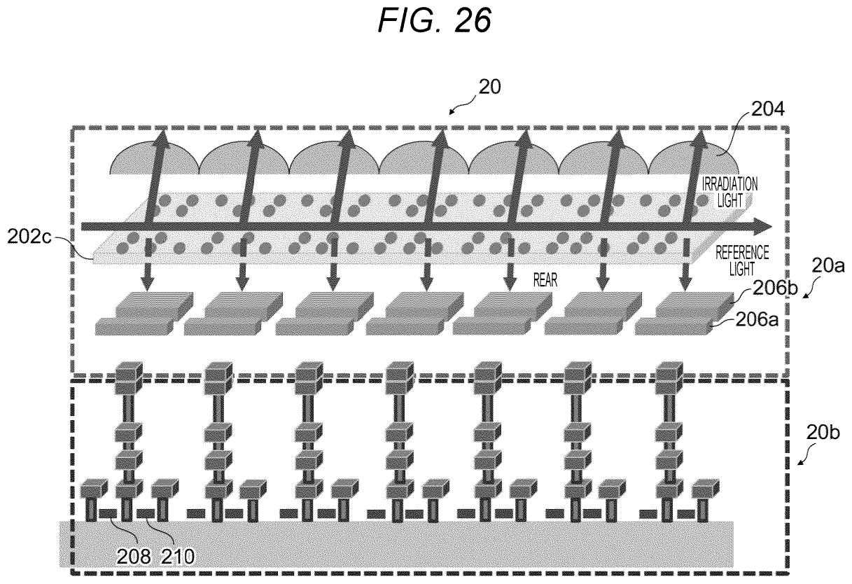

FIG. 26 is a diagram showing an example in which a light emitting unit 202c has a photonics structure. As shown in FIG. 26, incident light to the light emitting unit 202c is emitted in the upward direction or the downward direction by the photonics structure. As a result, the light emitted in the upward direction becomes measurement light, and the light emitted in the downward direction becomes reference light. In this manner, the light emitting unit 202c may have a photonics structure.

### (Configuration Example 2 of Plurality of Pixels 200)

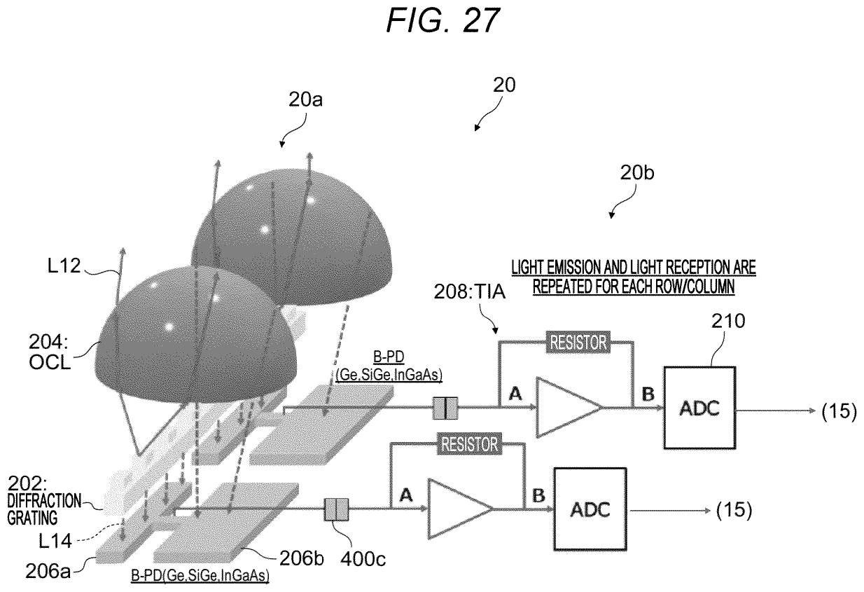

FIG. 27 is a diagram showing a configuration example of pixels 200 showing two adjacent pixels in one row. The optical circuit unit substrate 20a and the readout circuit substrate 20b are connected by the Cu—Cu connection 400c.

### (Configuration Example 2 of Pixel 200)

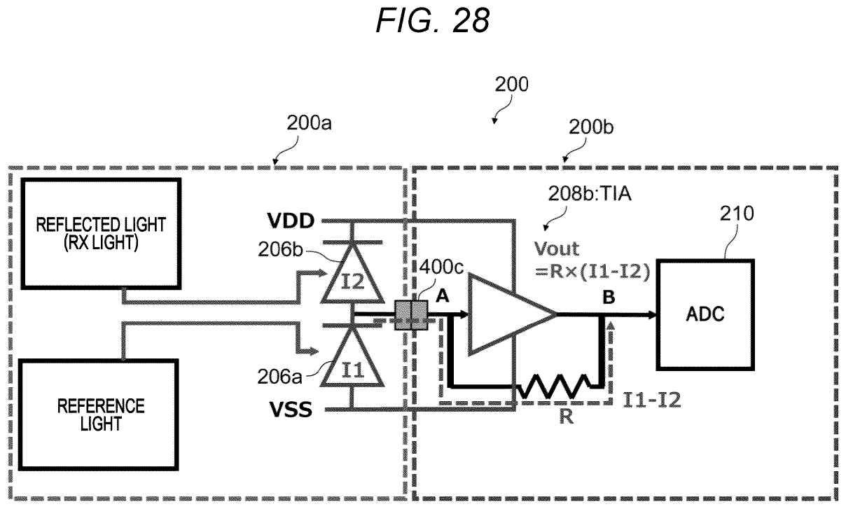

FIG. 28 is a diagram showing Configuration Example 2 of the pixel 200. As described above, a trans-impedance amplifier (TIA) 208b of the readout circuit unit 200b converts a difference current between a current I1 of the photodiode 206a and a current I2 of the photodiode 206b into a voltage, and as described above, the photoelectric conversion elements 206a and b are, for example, balanced photodiodes (Blanced PDs).

As shown in FIG. 28, one end of the photoelectric conversion element 206a is connected to a VSS power supply, and the other end is connected to one end of the photoelectric conversion element 206b and an input terminal A of a trans-impedance amplifier (TIA) 208b. The other end of the photoelectric conversion element 206b is connected to a VDD power supply. The VSS power supply is a ground voltage, for example, 0 V. The VDD power supply is on the high voltage side, and is, for example, 2.7 V. As described above, the optical circuit unit 200a is configured on the optical circuit unit substrate 20a (see FIGS. 8 and 9), and the readout circuit unit 200b is configured on the readout circuit substrate 20b (see FIGS. 8 and 9) called a read-out integrated circuit (ROIC).

The reference light is mainly incident on the photoelectric conversion element 206a. The return light (reflected light) is mainly incident on the photoelectric conversion element 206b. As a result, the photoelectric conversion element 206a generates the signal current I1 mainly based on the reference light. In addition, the photoelectric conversion element 206b generates the signal current I2 mainly based on the return light. As a result, the trans-impedance amplifier 208b outputs the input current I1-I2 input to the input terminal A to the output terminal B via a resistor R as a voltage Vout=R×(I1−I2). Thereafter, processing equivalent to that of the readout circuit unit 200b shown in FIG. 4 is performed.

### (Configuration Example 3 of Pixel 200)

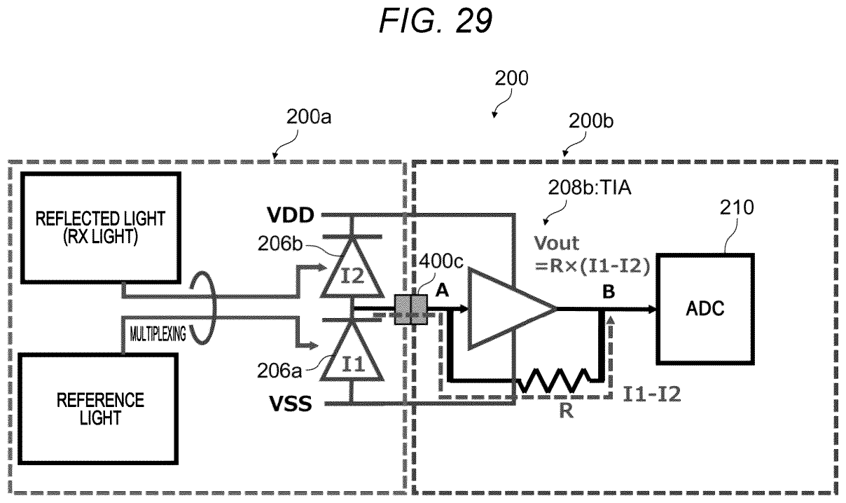

FIG. 29 is a diagram showing Configuration Example 3 of the pixel 200. Configuration Example 3 is different from the pixel 200 shown in FIG. 28 in that the reference light and the return light input to the photoelectric conversion elements 206a and b are multiplexed in advance. By multiplexing in advance, the signal current I1 and the signal current I2 can be set to substantially the same magnitude. As a result, for example, the signal of the input terminal A can be doubled.

### (Configuration Example 4 of Pixel 200)

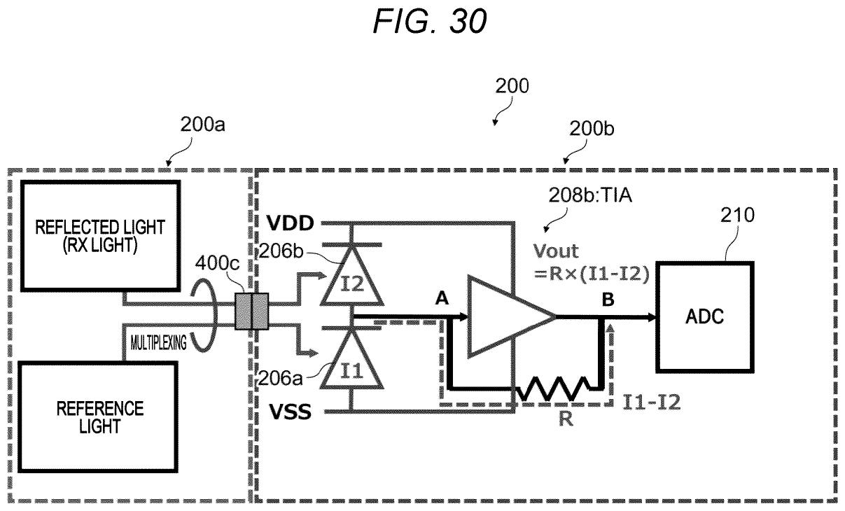

FIG. 30 is a diagram showing Configuration Example 4 of the pixel 200. Configuration Example 4 is different from the pixel 200 shown in FIG. 29 in connection positions of the optical circuit unit substrate 20a (see FIGS. 8 and 9) and the readout circuit substrate 20b (see FIGS. 8 and 9). That is, in Configuration Example 4 of the pixel 200 shown in FIG. 30, the optical circuit unit substrate 20a includes the light emitting unit 202, and the circuit board 20b includes the photoelectric conversion elements 206a and b, the trans-impedance amplifier 208b, and the analog-to-digital conversion circuit 210.

### (Processing Concept of Signal Processing Unit 15)

Here, a processing concept of the signal processing unit 15 (see FIG. 1) will be described.

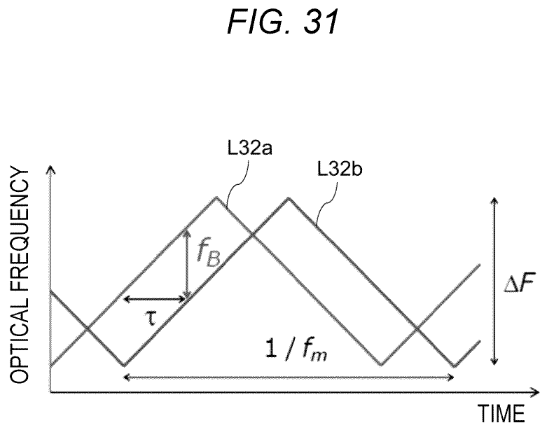

FIG. 31 is a diagram showing a relationship between reference light L32a and return light L32b. The horizontal axis represents the measurement time, and the vertical axis represents the frequency. τ represents a delay time, AF corresponds to a sweep frequency width fw, and 1/fm corresponds to a sweep time st. Assuming a beat frequency f_{B}, when a light speed c and a distance L are used, there is a relationship of f_{B}=2×fw×L/(st×c), and the distance L can be obtained on the basis of the beat frequency f_{B}.

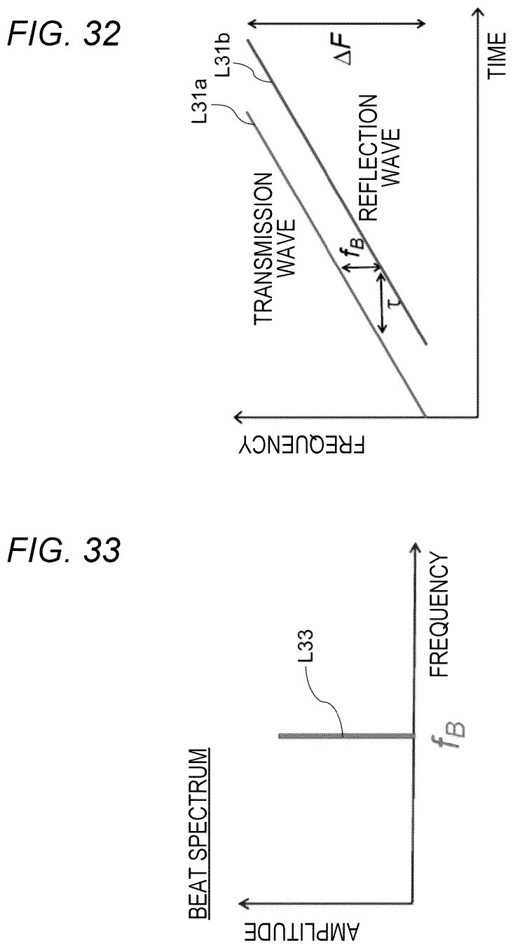

FIG. 32 is a diagram showing a relationship between a transmission wave signal L31a and a reflection wave signal L31b. The horizontal axis represents the measurement time, and the vertical axis represents the frequency. τ represents a delay time, and AF represents a frequency change range. The transmission wave signal L31a is a signal corresponding to the reference light L32a (see FIG. 31), and the reflection wave signal L31b is a signal corresponding to the return light L32b (see FIG. 31). That is, the transmission wave signal L31a is a signal corresponding to the reception of the reference light of the photoelectric conversion elements 206a and b, and the reflection wave signal L31b is a signal corresponding to the reception of the return light of the photoelectric conversion elements 206a and b. Therefore, as described above, the transmission wave signal L31a is output as the signal current I1, and the reflection wave signal L31b is output as the signal current I2.

FIG. 33 is a diagram showing the beat frequency f_{B} calculated by the processing unit 15. The horizontal axis represents the frequency, and the vertical axis represents the amplitude. As described above, the transmission wave signal L31a is output as the signal current I1, and the reflection wave signal L31b is output as the signal current I2. As can be seen from these, the beat frequency f is calculated by performing the frequency analysis of the beat signal based on the voltage Vout=R×(I1−I2). Then, the distance L can be calculated by the above-described relational expression between the beat frequency f_{B} and the distance L.

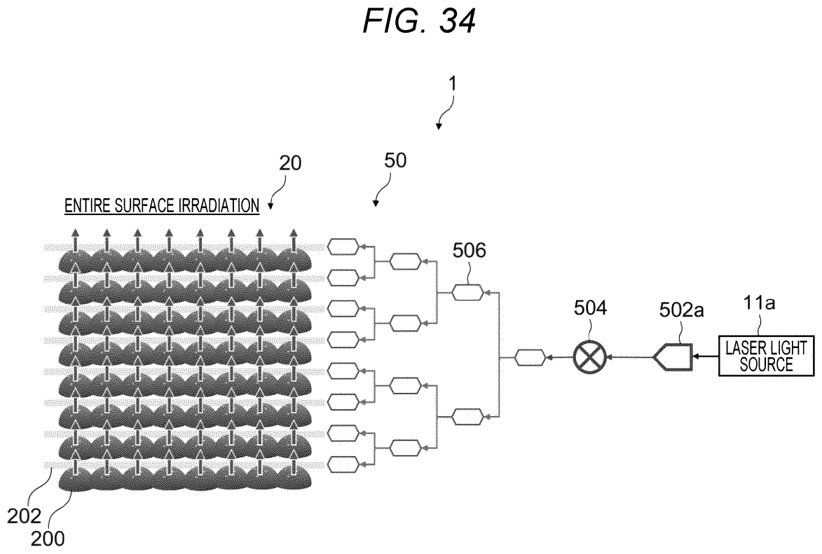

Here, an example of controlling light irradiation of the light emitting unit 202 of the pixel array unit 20 will be described with reference to FIGS. 34 to 43.

### (Control Example of Entire Surface Irradiation)

FIG. 34 is a diagram showing a control example of the entire surface irradiation of the pixel array unit 20. As shown in FIG. 34, the entire surface can be irradiated by causing the optical switch 506 to transmit light to all rows. The light of the laser light source 11a passes through a plurality of light receiving ends 502a and 502b (spot size converters) and the frequency modulation unit 504 (FM), and enters the optical switch 506 constructed with a plurality of switches. The light of the optical switch 506 is demultiplexed and distributed to the light emitting unit 202 arranged in each row of the pixel array unit 20. The light of all the rows is emitted to the measurement target Tg by being distributed to each row as equal light by the optical switch 506. The light of each pixel 200 is emitted at different times depending on the position of each pixel 200. However, since the light emitted from the pixel 200 returns to the pixel 200 as reflected light, the difference due to the physical position of the pixel at the emission time is canceled.

### (Control Example of One-Row Irradiation)

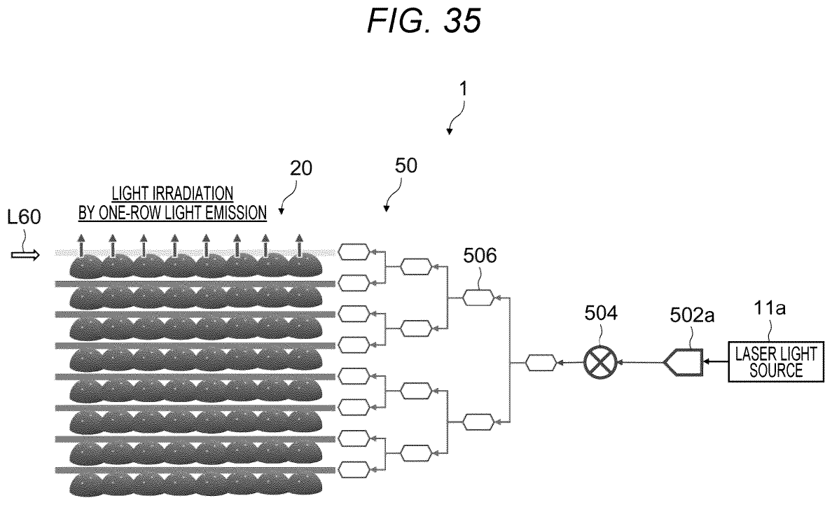

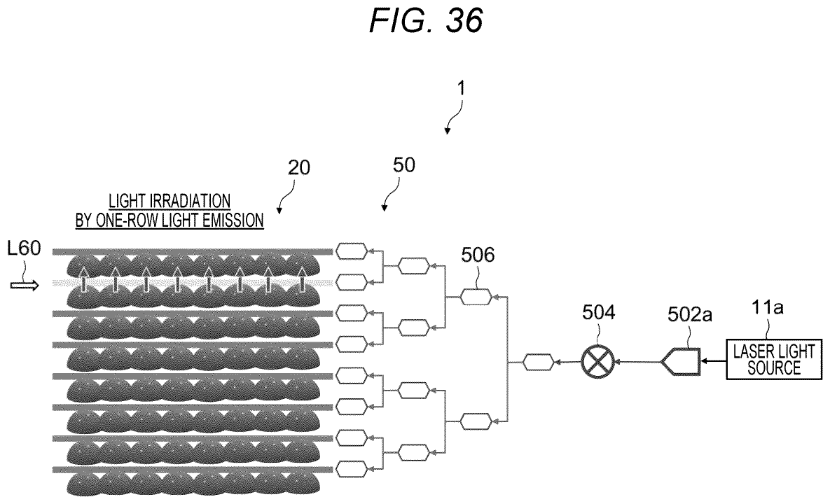

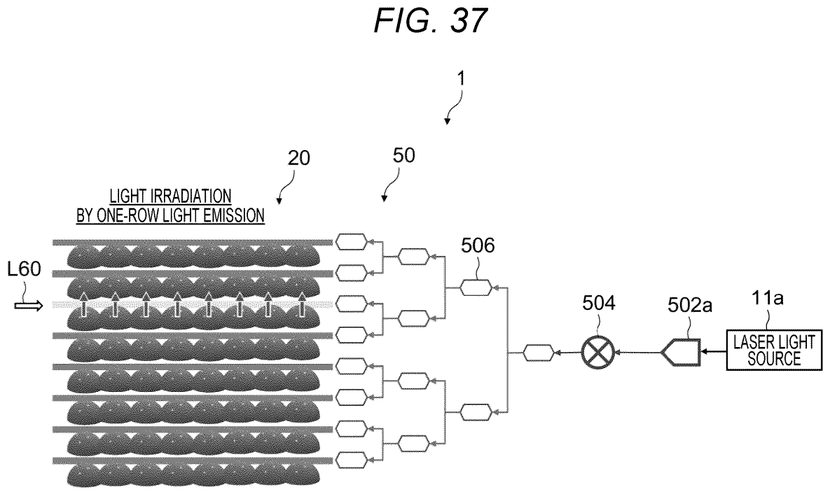

A control example of one-row irradiation of the pixel array unit 20 will be described with reference to FIGS. 35 to 37. FIG. 35 is a diagram showing an example in which the light emitting unit 202 in the first row indicated by the arrow L60 emits light. FIG. 36 is a diagram showing an example in which the light emitting unit 202 in the second row indicated by the arrow L60 emits light. FIG. 37 is a diagram showing an example in which the light emitting unit 202 in the third row indicated by the arrow L60 emits light. As shown in these drawings, in the control of the one row irradiation, each row of the pixel array unit 20 is sequentially irradiated one by one. In this case, the number of rows to be irradiated as the irradiation range may be limited. Alternatively, the irradiation may be performed every few rows.

As shown in FIGS. 35 to 37, the light of the laser light source 11a is distributed only to the first row of the pixel array unit 20 in the driving method. Therefore, the light distributed to N rows, which is all the rows of the pixel array unit 20, can be concentrated on one row, so that the optical power can be improved. Alternatively, in a case where the optical power can be suppressed, the power of the light emitting unit (laser or the like) can be reduced to achieve low power consumption.

### (Control Example of Two-Row Irradiation)

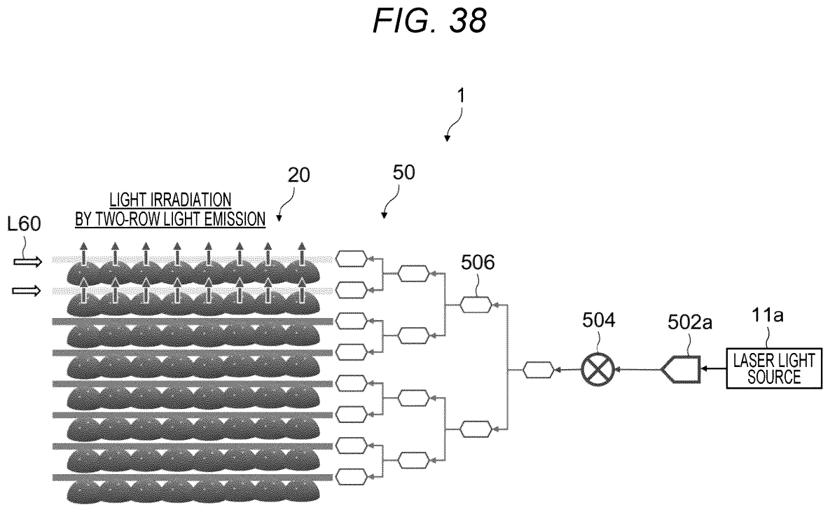

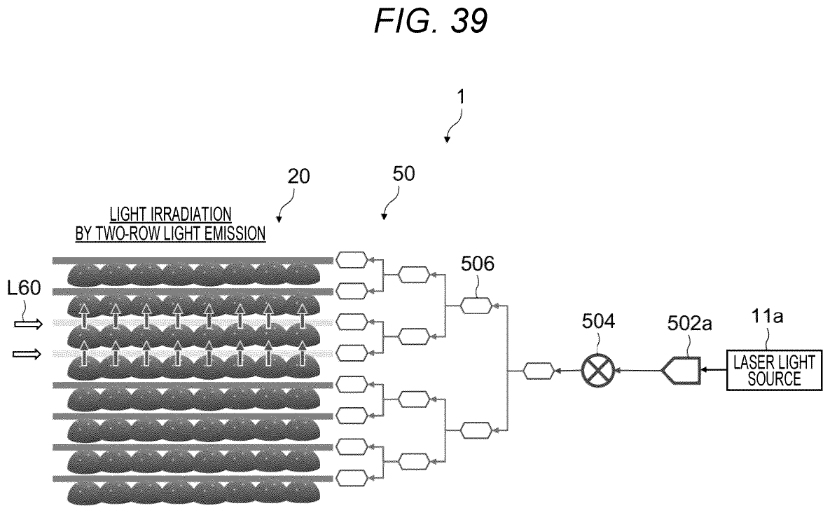

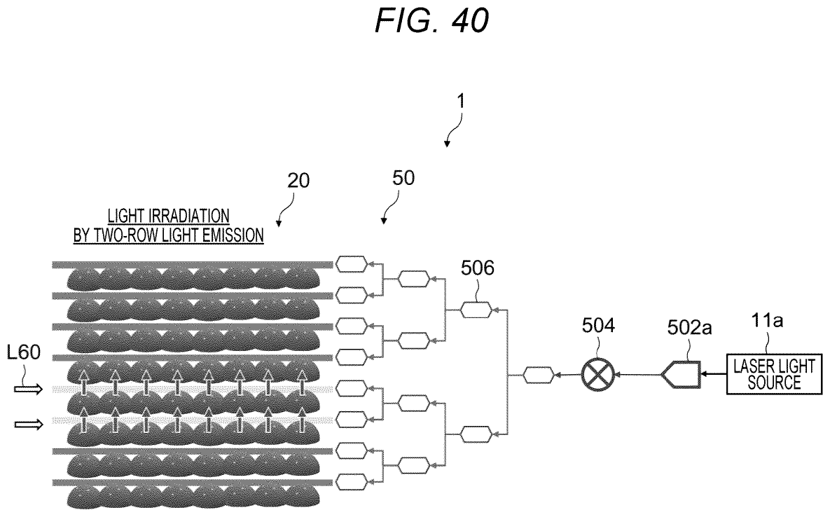

A control example of two-row irradiation of the pixel array unit 20 will be described with reference to FIGS. 38 to 40. FIG. 38 is a diagram showing an example in which the light emitting units 202 in the first and second rows indicated by the arrows L60 emit light. FIG. 39 is a diagram showing an example in which the light emitting units 202 in the third and fourth rows indicated by the arrow L60 emit light. FIG. 40 is a diagram showing an example in which the light emitting units 202 in the fifth and sixth rows indicated by the arrow L60 emit light. As shown in these drawings, in the control of two-row irradiation, each row of the pixel array unit 20 is sequentially irradiated by two rows. In this case, the number of rows to be irradiated as the irradiation range may be limited. Alternatively, the irradiation may be performed every few rows.

As shown in FIGS. 38 to 40, the light of the laser light source 11a is distributed only to two rows of the pixel array unit 20 in the driving method. Therefore, the time for reading all the rows can be halved as compared with one-row irradiation, and the imaging frame rate of the distance image can be increased.

### (Control Example of Three-Row Irradiation)

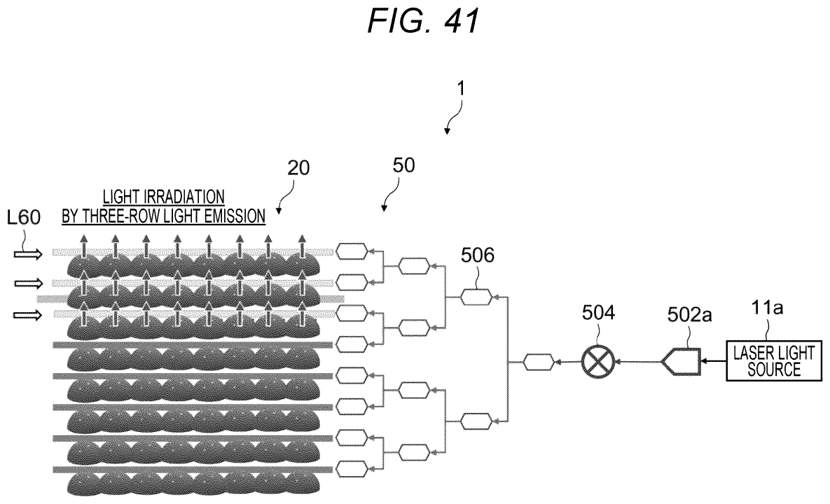

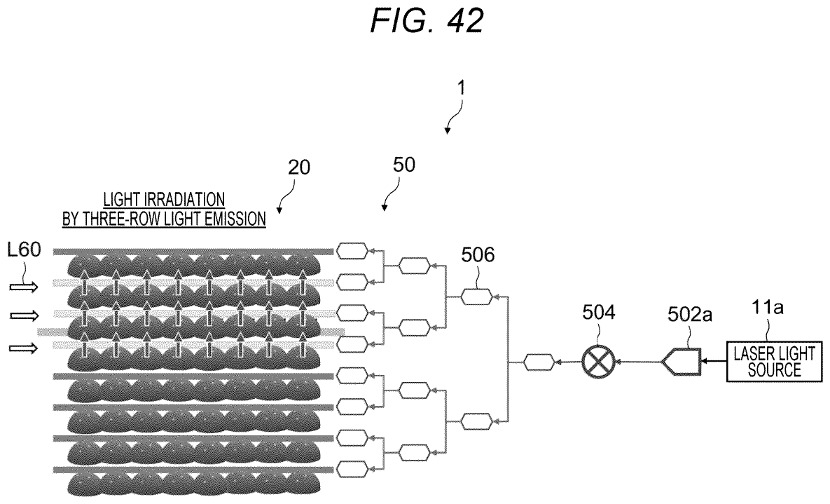

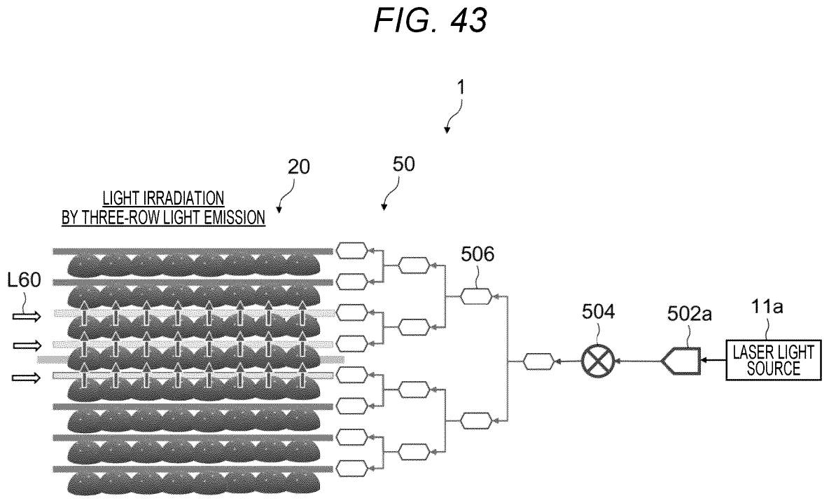

A control example of three-row irradiation of the pixel array unit 20 will be described with reference to FIGS. 41 to 43. FIG. 41 is a diagram showing an example in which the light emitting units 202 in the first to third rows indicated by the arrow L60 emit light. FIG. 42 is a diagram showing an example in which the light emitting units 202 in the second to fourth rows indicated by the arrow L60 emit light. FIG. 43 is a diagram showing an example in which the light emitting units 202 in the third to fifth rows indicated by the arrow L60 emit light. As shown in these drawings, since the pixels of three rows emit light, it is possible to triple the intensity of light, for example, as compared with FIGS. 35 to 37. That is, since the signal is detected only in the middle row, there is a component in which the reflected light of the upper and lower light is detected even in the middle pixel, so that the detection sensitivity can be increased. In this case, the light reception is shifted row by row.

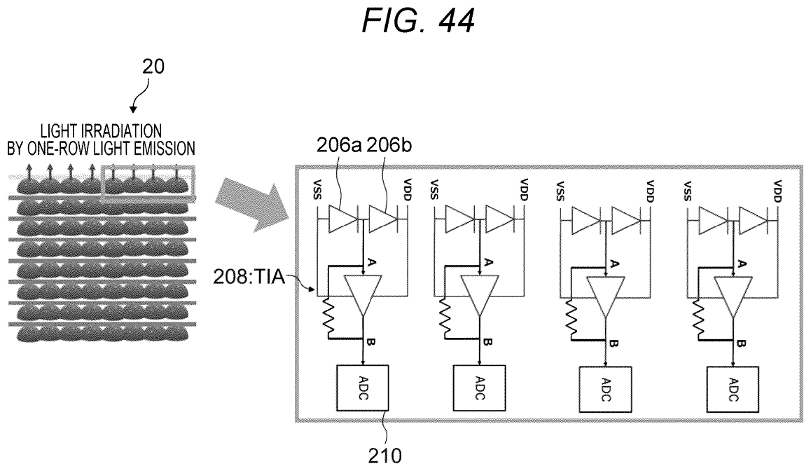

Here, a configuration example of the pixel array unit 20 will be described with reference to FIGS. 44 to 60.

### (Circuit Configuration Example Corresponding to FIG. 10)

FIG. 44 is a diagram showing a configuration example of the pixel 200 corresponding to FIG. 10. A circuit diagram of a pixel 200 corresponding to a rectangular range in the pixel array unit 20 is schematically shown. Here, the configurations of the photoelectric conversion elements 206a and 206b, the trans-impedance amplifier 208b, and the analog-to-digital conversion circuit 210 are shown. As shown in FIG. 44, an equivalent circuit for four pixels in which pixels are arranged in the row direction is shown. The circuits corresponding to the respective pixels are independent, and the pixel signals can be output independently.

### (Analog-to-Digital Conversion Circuit 210 is Shared by Two Pixels)

### (Configuration Example 3 of Plurality of Pixels 200)

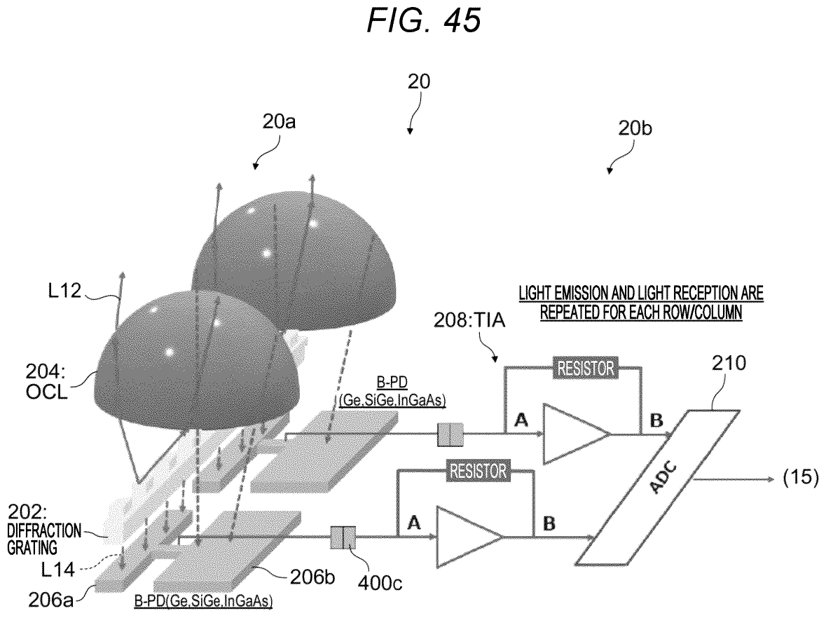

FIG. 45 is a diagram showing Configuration Example 3 of the plurality of pixels 200. Configuration Example 3 is different from the configuration of the plurality of pixels 200 shown in FIG. 27 in that the analog-to-digital conversion circuit 210 is shared by two pixels.

### (Circuit Configuration Example Corresponding to FIG. 45)

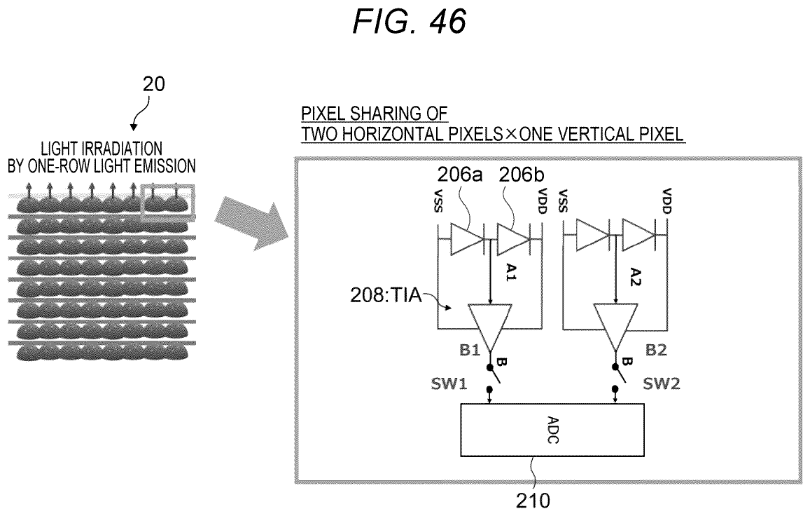

FIG. 46 is a diagram showing a configuration example of the pixel 200 corresponding to FIG. 45. A circuit diagram of a pixel 200 corresponding to a rectangular range in the pixel array unit 20 is schematically shown. Here, the configurations of the photoelectric conversion elements 206a and 206b, the trans-impedance amplifier 208, and the analog-to-digital conversion circuit 210 are shown. The trans-impedance amplifier 208 on an A1 side is connected to the analog-to-digital conversion circuit 210 via a switch SW1, and the trans-impedance amplifier 208 on an A2 side is connected thereto via a switch SW2. In addition, signals from the photoelectric conversion elements 206a and 206b on the A1 side are converted into a voltage signal B1 through the trans-impedance amplifier 208. Similarly, signals from the photoelectric conversion elements 206a and 206b on the A2 side are converted into a voltage signal B2 through the trans-impedance amplifier 208. Then, the voltage signal B1 or the voltage signal B2 is converted into a digital signal by switching ON/OFF of the switches SW1 and SW2. As described above, by sharing the analog-to-digital conversion circuit 210, the pixel array unit 20 can be further downsized.

### (Configuration Example 4 of Plurality of Pixels 200)

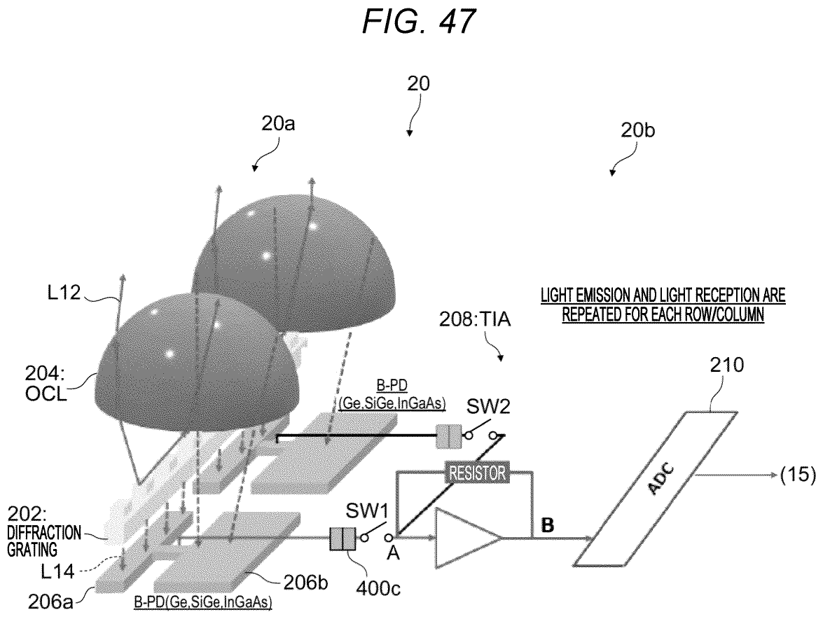

FIG. 47 is a diagram showing Configuration Example 4 of the plurality of pixels 200. For example, FIG. 47 is an example of a pixel cross-sectional view in one row direction. Configuration Example 4 is different from the arrangement of the plurality of pixels 200 shown in FIG. 45 in that the trans-impedance amplifier 208 is further shared by two pixels.

### (Circuit Configuration Example Corresponding to FIG. 47)

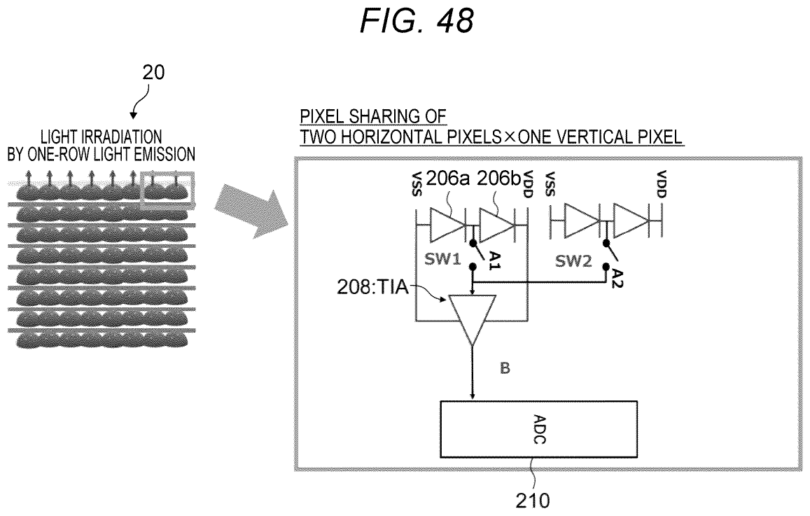

FIG. 48 is a diagram showing a configuration example of the pixel 200 corresponding to FIG. 47. A circuit diagram of a pixel 200 corresponding to a rectangular range in the pixel array unit 20 is schematically shown. Here, the configurations of the photoelectric conversion elements 206a and 206b, the trans-impedance amplifier 208, and the analog-to-digital conversion circuit 210 are shown. The photoelectric conversion elements 206a and 206b on the A1 side are connected to the trans-impedance amplifier 208 via the switch SW1, and the photoelectric conversion elements 206a and 206b on the A2 side are connected thereto via the switch SW2. In addition, each signal is converted into a voltage signal B through the trans-impedance amplifier 208. Thus, by sharing the trans-impedance amplifier 208, the pixel array unit 20 can be further downsized.

### (Configuration Example 5 of Plurality of Pixels 200)

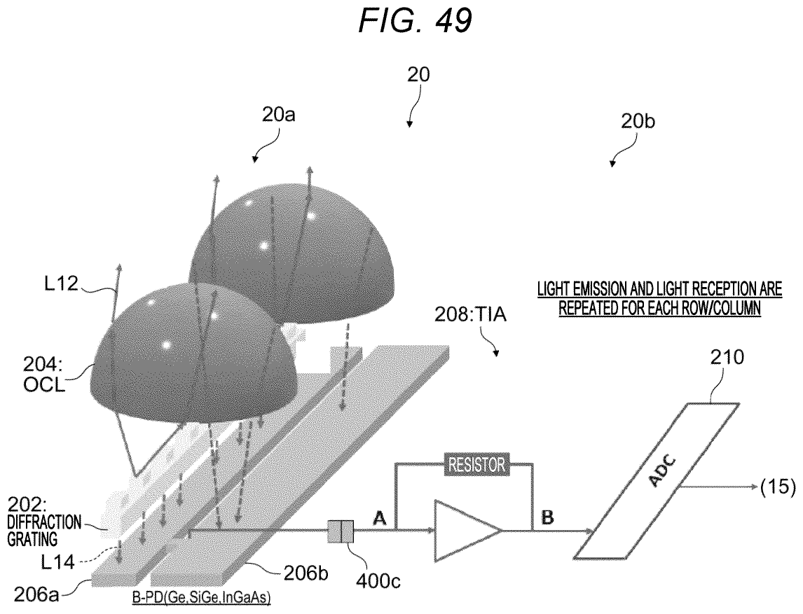

FIG. 49 is a diagram showing Configuration Example 5 of the plurality of pixels 200. For example, FIG. 49 is an example of a pixel cross-sectional view in one row direction. Configuration Example 5 is different from the arrangement of the plurality of pixels 200 shown in FIG. 47 in that the photoelectric conversion elements 206a and 206b are further shared by two pixels. The light transmitted through the two microlenses 204 is simultaneously received by the photoelectric conversion elements 206a and 206b.

### (Circuit Configuration Example Corresponding to FIG. 49)

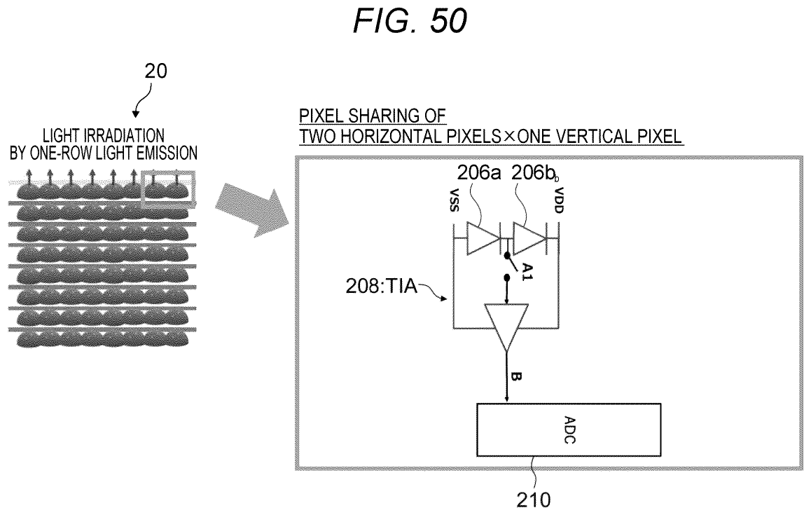

FIG. 50 is a diagram showing a configuration example of the pixel 200 corresponding to FIG. 49. A circuit diagram of a pixel 200 corresponding to a rectangular range in the pixel array unit 20 is schematically shown. Here, the configurations of the photoelectric conversion elements 206a and 206b, the trans-impedance amplifier 208, and the analog-to-digital conversion circuit 210 are shown. The photoelectric conversion elements 206a and 206b are connected to the trans-impedance amplifier 208, and the trans-impedance amplifier 208 is connected to the analog-to-digital conversion circuit 210. When the photoelectric conversion elements 206a and 206b are shared by a plurality of pixels, the light receiving sensitivity can be improved although the resolution is reduced. Note that, in FIG. 50, one photoelectric conversion element 206a or 206b is configured for two pixels, but the present invention is not limited thereto. For example, one photoelectric conversion element 206a or 206b may be shared by three or more pixels.

### (Four Pixels Share Analog-to-Digital Conversion Circuit 210)

### (Configuration Example 6 of Plurality of Pixels 200)

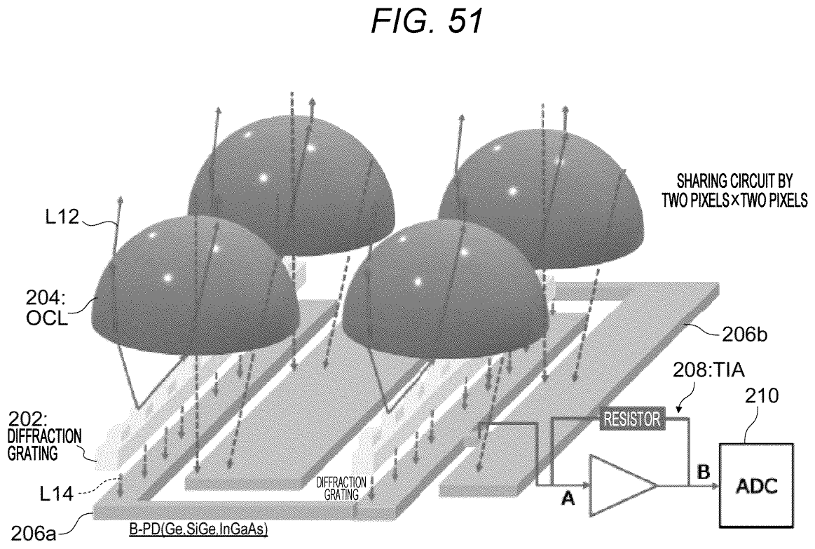

FIG. 51 is a diagram showing Configuration Example 6 of the plurality of pixels 200. Configuration Example 6 is different from the arrangement of the plurality of pixels 200 shown in FIG. 49 in that the photoelectric conversion elements 206a and 206b are shared by four pixels. The light transmitted through the four microlenses 204 is simultaneously received by the photoelectric conversion elements 206a and 206b.

### (Circuit Configuration Example Corresponding to FIG. 51)

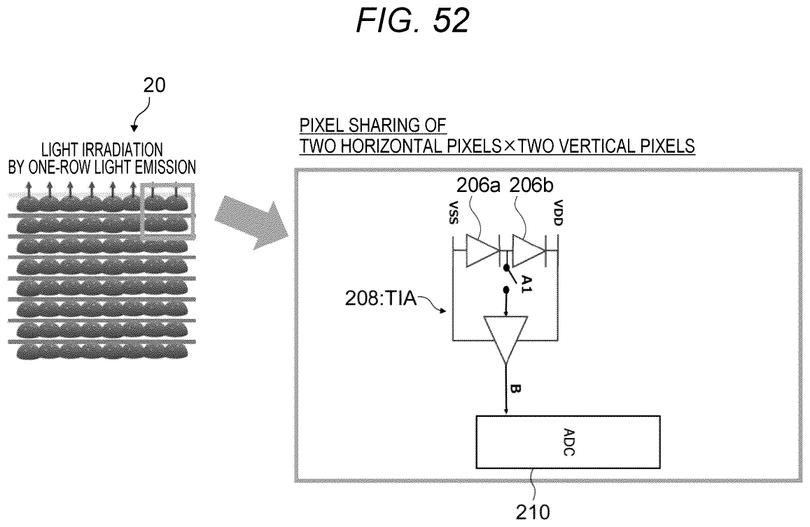

FIG. 52 is a diagram showing a configuration example of the pixel 200 corresponding to FIG. 51. A circuit diagram of a pixel 200 corresponding to a rectangular range in the pixel array unit 20 is schematically shown. Here, the configurations of the photoelectric conversion elements 206a and 206b, the trans-impedance amplifier 208, and the analog-to-digital conversion circuit 210 are shown. The photoelectric conversion elements 206a and 206b are connected to the trans-impedance amplifier 208, and the trans-impedance amplifier 208 is connected to the analog-to-digital conversion circuit 210. When the photoelectric conversion elements 206a and 206b are shared by four pixels, the light receiving sensitivity can be further improved although the resolution is reduced.

### (Analog-to-Digital Conversion Circuit 210 is Shared by Pixels in Column Direction)

### (Configuration Example 7 of Plurality of Pixels 200)

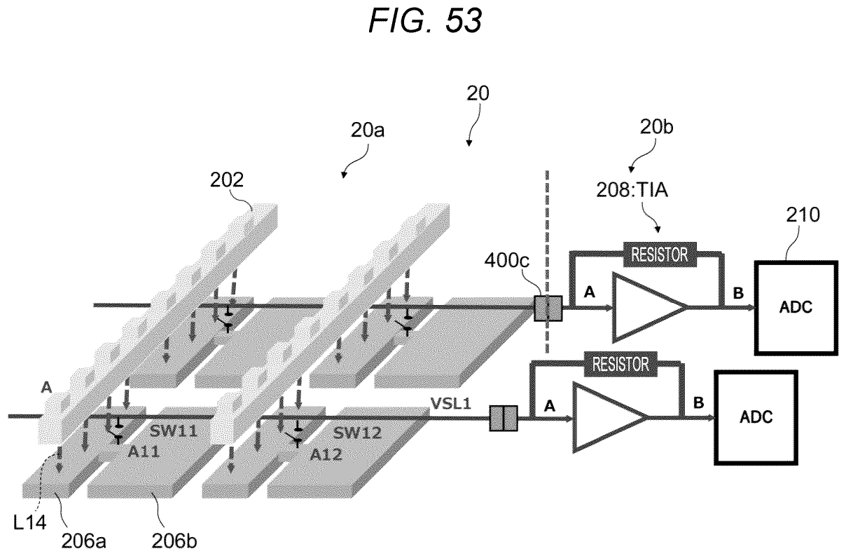

FIG. 53 is a diagram showing Configuration Example 7 of the plurality of pixels 200. Configuration Example 7 is different from the arrangement of the plurality of pixels 200 shown in FIG. 10 in that the photoelectric conversion elements 206a and 206b are shared by pixels in the column direction. Furthermore, in the pixel array unit 20 shown in FIG. 53, illustration of the microlens 204 is omitted.

### (Circuit Configuration Example 1 Corresponding to FIG. 53)

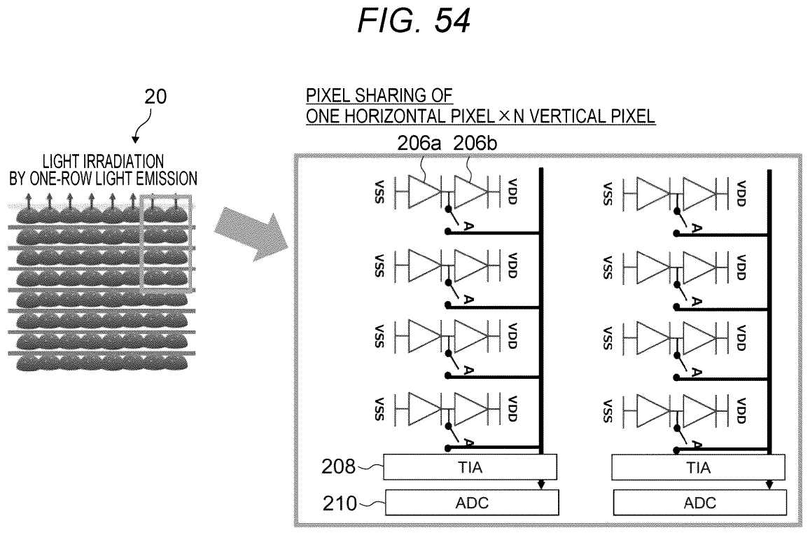

FIG. 54 is a diagram showing a configuration example of the pixel 200 corresponding to FIG. 53. A circuit diagram of a pixel 200 corresponding to a rectangular range in the pixel array unit 20 is schematically shown. Here, the configurations of the photoelectric conversion elements 206a and 206b, the trans-impedance amplifier 208, and the analog-to-digital conversion circuit 210 are shown. The photoelectric conversion elements 206a and 206b arranged in a column are connected to the trans-impedance amplifier 208 via a switch A, and the trans-impedance amplifier 208 is connected to the analog-to-digital conversion circuit 210. As a result, an output signal VSLI (see FIG. 53) is converted into a signal B by the trans-impedance amplifier 208 and is converted into a digital signal by the analog-to-digital conversion circuit 210. In this manner, the trans-impedance amplifier 208 and the analog-to-digital conversion circuit 210 are shared by the pixels arranged in a column of the pixel array unit 20. As a result, the pixel array unit 20 can be further downsized. Note that the trans-impedance amplifier 208 and the analog-to-digital conversion circuit 210 are arranged in a column outside the pixel. For example, the trans-impedance amplifier 208 and the analog-to-digital conversion circuit 210 may be disposed in the horizontal drive unit 40 (see FIG. 2).

(Circuit Configuration Example 2 in which Analog-to-Digital Conversion Circuit 210 is Shared by Pixels in Column Direction)

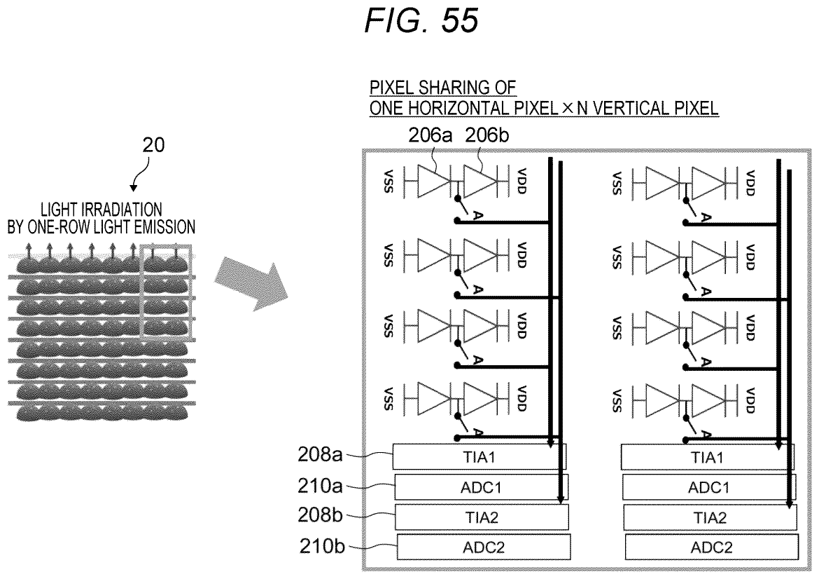

FIG. 55 is a diagram showing Configuration Example 2 of the pixel 200 in which the analog-to-digital conversion circuit 210 is shared by the pixels in the column direction. Configuration Example 2 is different from the circuit configuration example shown in FIG. 54 in that the photoelectric conversion elements 206a and 206b in which two trans-impedance amplifiers 208a and b and two analog-to-digital conversion circuits 210a and b are arranged in a column are connected via the switch A. For example, the rows are divided into odd rows and even rows, and the signals are converted into digital values by two sets of trans-impedance amplifiers 208a and b and analog-to-digital conversion circuits 210a and b, respectively. As a result, the frame rate can be sped up to about 2 times the circuit configuration example shown in FIG. 54. In this case, in the connection method (sharing method) to the trans-impedance amplifiers 208a and b and the analog-to-digital conversion circuit 210a, the rows may be divided into even rows and odd rows. Alternatively, the rows may be divided by two rows such that the trans-impedance amplifier 208a is for the first row and the second row, and the trans-impedance amplifier 208 is for the third row and the fourth row. In this manner, by including the plurality of trans-impedance amplifiers 208a and b and the analog-to-digital conversion circuits 210a and b, the degree of freedom in circuit design can be increased. This makes it possible to achieve a circuit arrangement (layout) that further enhances circuit characteristics.

(Circuit Configuration Example 3 in which Analog-to-Digital Conversion Circuit 210 is Shared by Pixels in Column Direction)

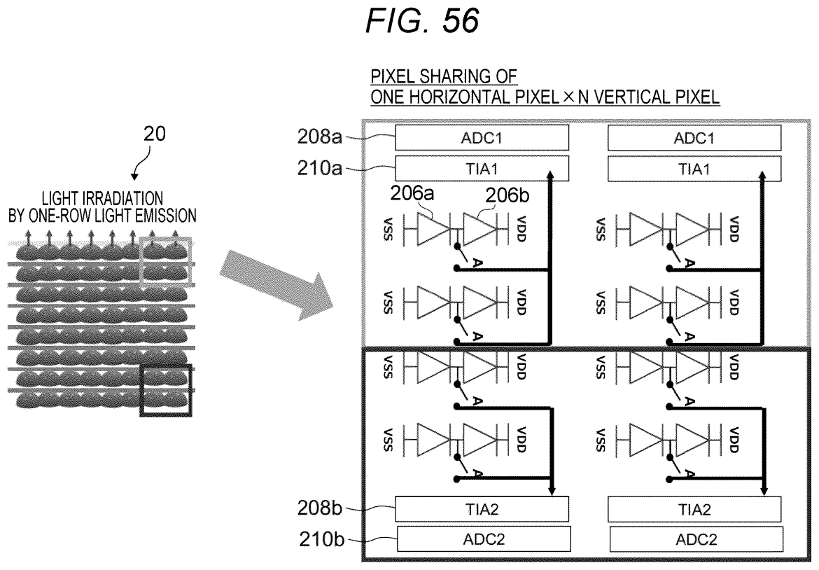

FIG. 56 is a diagram showing Configuration Example 3 of the pixel 200 in which the analog-to-digital conversion circuit 210 is shared by the pixels in the column direction. The photoelectric conversion elements 206a and 206b in which the two trans-impedance amplifiers 208a and b and the two analog-to-digital conversion circuits 210a and b are arranged in a column are connected via the switch A. This case is different from the circuit configuration example 3 shown in FIG. 55 in that one set of the trans-impedance amplifiers 208a and b and the two analog-to-digital conversion circuits 210a and b is arranged at one end and the other set is arranged at the other end.

As a result, the pixel array unit 20 is divided into a pixel group arranged in the upper portion and a pixel group arranged in the lower portion, and the pixel group arranged in the upper portion is read by the trans-impedance amplifier 208a and the analog-to-digital conversion circuit 210a. The pixel group arranged in the lower part is read out by the trans-impedance amplifier 208 and the analog-to-digital conversion circuit 210b. As a result, the frame rate can be sped up by about 2 times as compared with the configuration example shown in FIG. 54.

### (Configuration Example 8 of Plurality of Pixels 200)

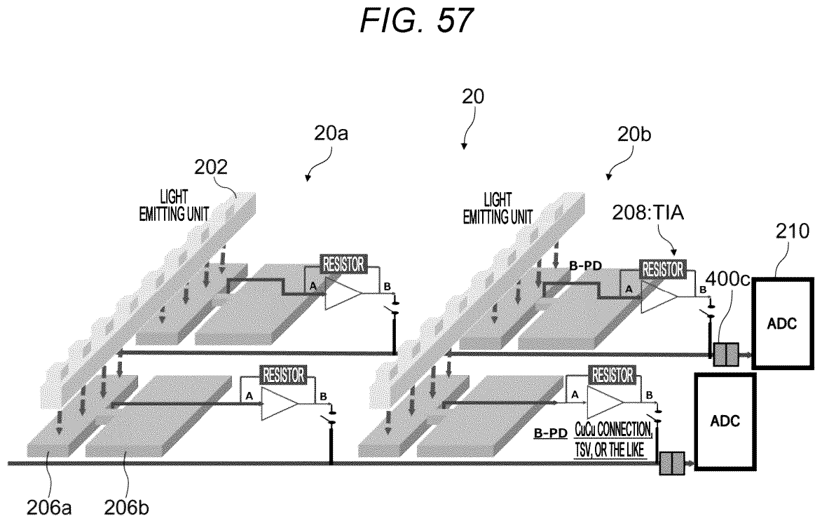

FIG. 57 is a diagram showing Configuration Example 8 of the plurality of pixels 200. Configuration Example 8 is different from the arrangement of the plurality of pixels 200 shown in FIG. 53 in that the trans-impedance amplifier 208a is arranged in each pixel. With such a circuit, the size of each pixel can be reduced, and the chip area of the pixel array unit 20 can be reduced.

### (Configuration Example 9 of Plurality of Pixels 200)

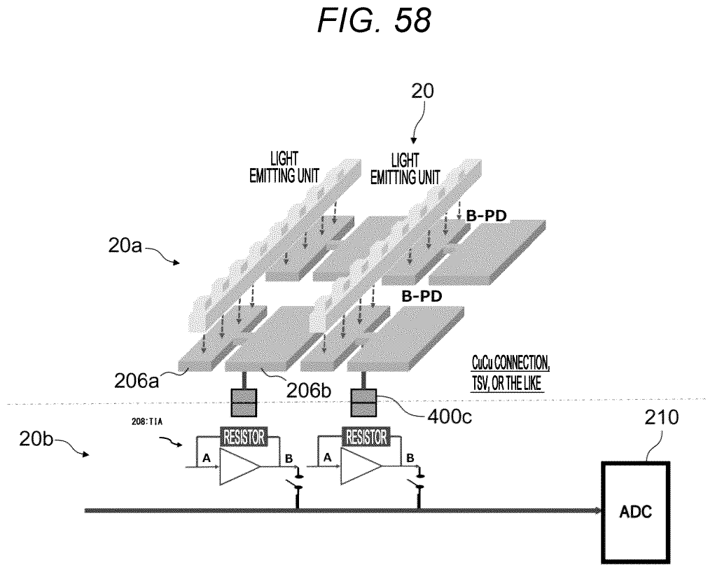

FIG. 58 is a diagram showing Configuration Example 9 of the plurality of pixels 200. The configuration example is different from the configuration example shown in FIG. 57 in that the photoelectric conversion elements 206a and 206b arranged in the column direction are stacked on the upper layer, and the trans-impedance amplifiers 208a and b, the analog-to-digital conversion circuits 210a and b, and the switching elements are stacked on the lower layer.

### (Circuit Configuration Example Corresponding to FIGS. 57 and 58)

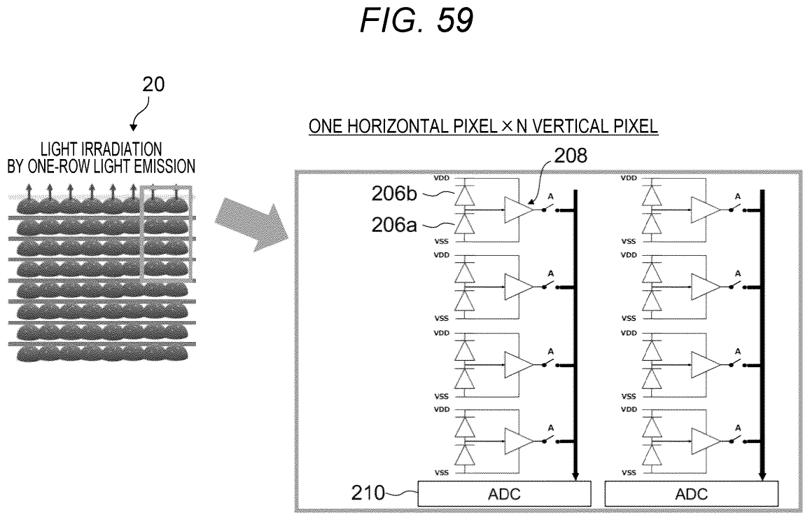

FIG. 59 is a diagram showing a configuration example of the pixel 200 corresponding to FIGS. 57 and 58. The analog-to-digital conversion circuit 210 is shared by pixels in the column direction. Each of the photoelectric conversion elements 206a and 206b is connected to the analog-to-digital conversion circuit 210 via the trans-impedance amplifier 208a and the switching element A in the same pixel. With such a circuit, the size of each pixel can be reduced, and the chip area of the pixel array unit 20 can be further reduced.

### (Configuration Example 10 of Plurality of Pixels 200)

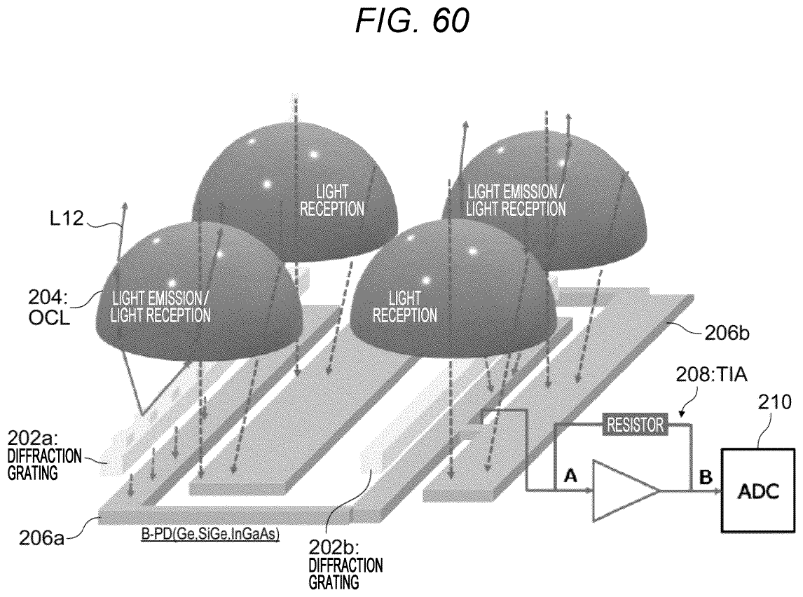

FIG. 60 is a diagram showing Configuration Example 10 of the plurality of pixels 200. Configuration Example 10 is different from the configuration example shown in FIG. 51 in that a periodic diffraction grating is not provided for one pixel of the light emitting units 202a and b. With such a configuration of the light emitting units 202a and b, the measurement light and the reference light are emitted from two pixels among four pixels. On the other hand, since the reference light is not emitted to the other two pixels among the four pixels, it is possible to mainly receive the return light. In this manner, it is possible to cause the pixel that emits light and the pixel that receives light to separately function. This makes it possible to suppress color mixing between the emitted wave and the reflection wave.

### (Configuration Example of Photodetection Element 1 Capable of Visible Imaging and Infrared Imaging)

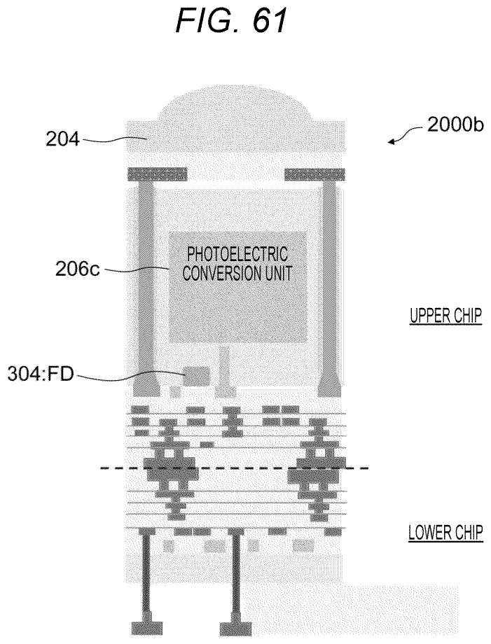

A configuration example of the photodetection element 1 capable of visible imaging and infrared imaging will be described with reference to FIGS. 61 to 72.

FIG. 61 is a diagram showing a configuration example of a pixel 2000b capable of visible imaging. As shown in FIG. 61, the pixel 2000b includes at least a microlens 204, a photoelectric conversion element (photoelectric conversion unit) 206c, and a floating diffusion (Fd) 304. The photoelectric conversion element 206c is, for example, a visible light sensor, and photoelectrically converts light having a wavelength λ of 400 nm to 700 nm. The floating diffusion 304 can accumulate electrons photoelectrically converted by the photoelectric conversion element 206c.

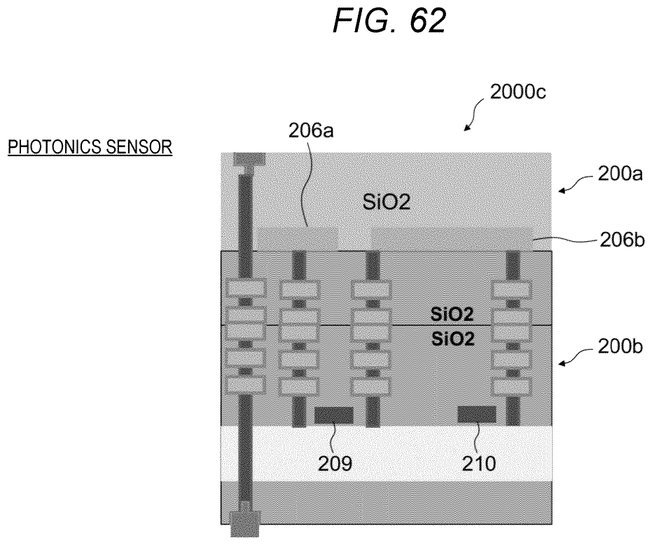

FIG. 62 is a cross-sectional view showing a configuration example of a pixel 2000c capable of infrared imaging. As shown in FIG. 62, the optical circuit unit 200a and the readout circuit unit 200b are stacked. The optical circuit unit 200a includes photoelectric conversion elements 206a and 206b. In the photoelectric conversion element 206a and the photoelectric conversion element 206b, wavelength bands having sensitivity are shifted. Therefore, the photoelectric conversion element 206a and the photoelectric conversion element 206b can perform spectroscopy. More specifically, the photoelectric conversion element 206a and the photoelectric conversion element 206b are made of different materials. For example, the photoelectric conversion element 206a and the photoelectric conversion element 206b can detect two kinds of light of 1550 nm and 2000 nm among light of a wavelength band of 1100 nm or more which is not absorbed by silicon. This makes it possible to separate and detect a wavelength in the vicinity of 1550 nm, which has been generally difficult to implement so far.

The readout circuit unit 200b includes a floating diffusion 209 and an analog-to-digital conversion circuit 210. For example, the readout circuit unit 200b is configured on a silicon oxide (SiO₂) layer. In this case, a silicon oxide (SiO₂) layer may be stacked on a silicon-on-insulator (SOI) substrate or a silicon (Si) substrate. In such a stacked structure, the optical circuit unit 200a and the readout circuit unit 200b can be stacked by connecting copper (Cu) wires to each other or connecting them by a through silicon via TSV or the like.

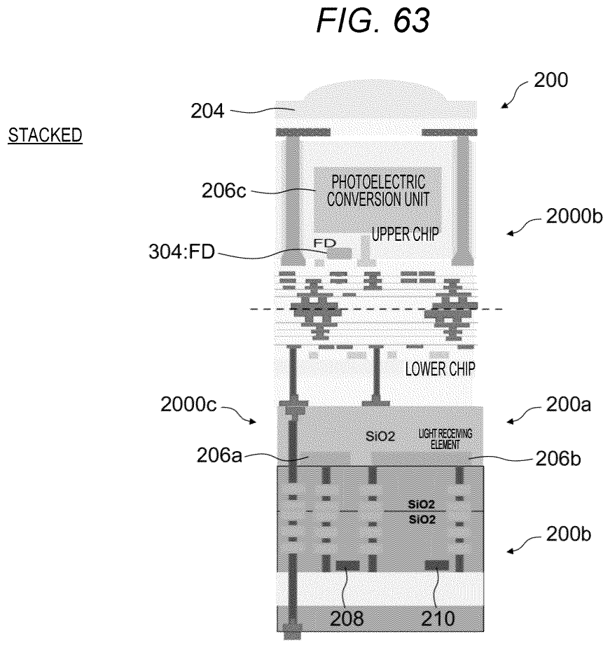

FIG. 63 is a cross-sectional view of a pixel in which the pixel 2000b capable of visible imaging and the pixel 2000c capable of infrared imaging are further stacked. Blue light, green light, and red light, which are visible light, are absorbed on the pixel 2000b side. However, since the near-infrared light having a long wavelength is not absorbed on the pixel 2000b side, the near-infrared light passes through the upper chip and is photoelectrically converted by the photodetection element of the lower chip. For example, light of 1550 nm, 1330 nm, 2000 nm, or the like cannot be received by the visible light sensor, and thus is photoelectrically converted by the photoelectric conversion elements 206a and 206b of the lower chip. This enables imaging of a visible image and an infrared image. Furthermore, in such a stereoscopic photodetection element 1, since the pixel 2000b capable of visible imaging and the pixel 2000c capable of infrared imaging are stacked, the resolution can be higher than that of the planar type.

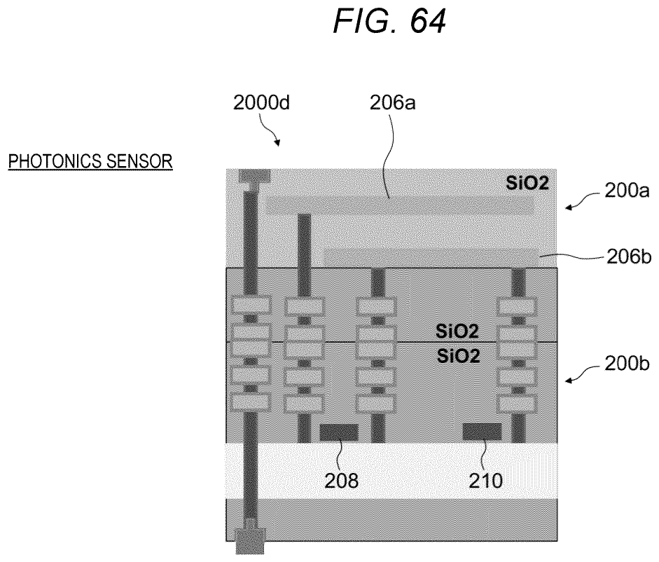

FIG. 64 is a cross-sectional view showing a configuration example of a pixel 2000d capable of infrared imaging. As shown in FIG. 64, the configuration example is different from the pixel 2000c in that the photoelectric conversion element 206a and the optical element 206b are stacked.

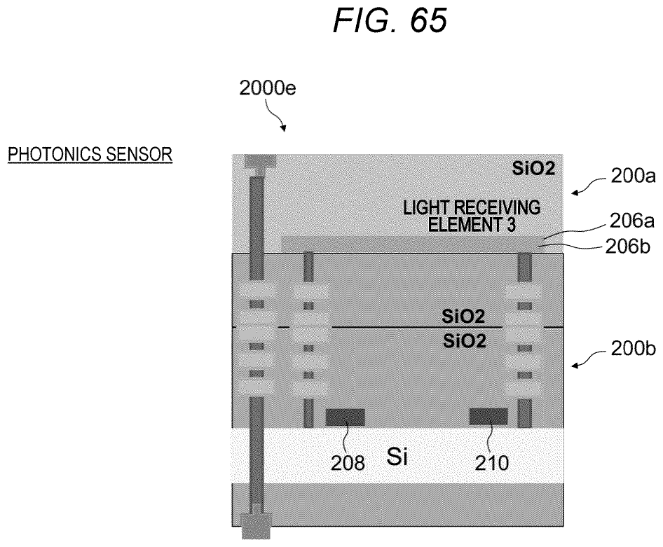

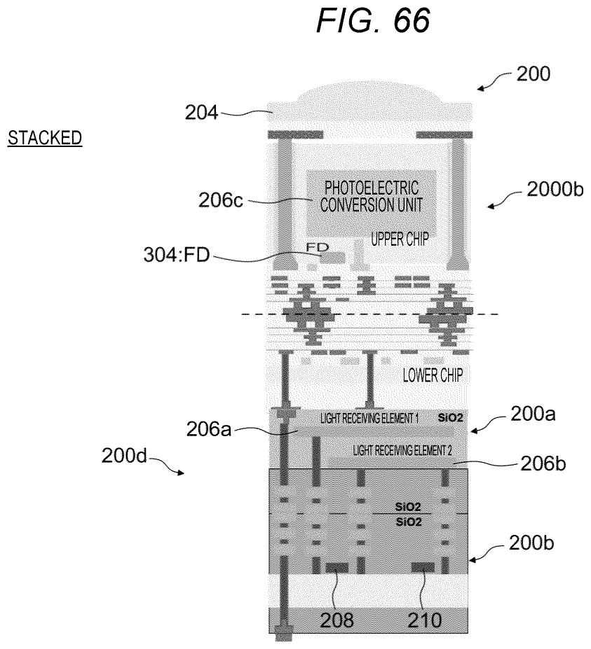

FIG. 65 is a cross-sectional view showing a configuration example of a pixel 2000e capable of infrared imaging. As shown in FIG. 65, the configuration example is different from the pixel 2000d in that the photoelectric conversion element 206a and the optical element 206b are integrally stacked. As a result, the light receiving areas of the photoelectric conversion element 206a and the optical element 206b can be further expanded.

FIG. 66 is a cross-sectional view of a pixel in which the pixel 2000b capable of visible imaging and the pixel 2000d capable of infrared imaging are further stacked. Blue light, green light, and red light, which are visible light, are absorbed on the pixel 2000b side. However, since the near-infrared light having a long wavelength is not absorbed on the pixel 2000b side, the near-infrared light passes through the upper chip and is photoelectrically converted by the photodetection element of the lower chip. For example, light of 1550 nm, 1330 nm, 2000 nm, or the like cannot be received by the visible light sensor, and thus is photoelectrically converted by the photoelectric conversion elements 206a and 206b of the lower chip. This enables imaging of a visible image and an infrared image. Furthermore, in such a stereoscopic photodetection element 1, since the pixel 2000b capable of visible imaging and the pixel 2000d capable of infrared imaging are stacked, the resolution can be higher than that of the planar type.

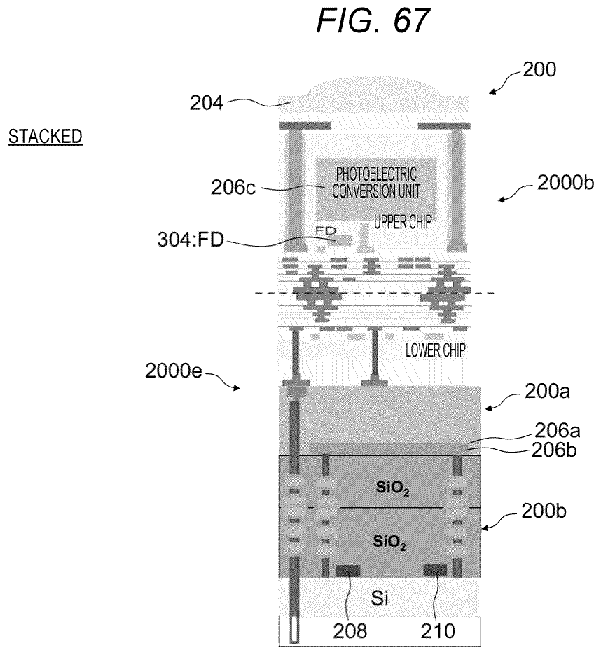

Similarly, FIG. 67 is a cross-sectional view of a pixel in which the pixel 2000b capable of visible imaging and the pixel 2000e capable of infrared imaging are further stacked. Blue light, green light, and red light, which are visible light, are absorbed on the pixel 2000b side. However, since the near-infrared light having a long wavelength is not absorbed on the pixel 2000b side, the near-infrared light passes through the upper chip and is photoelectrically converted by the photodetection element of the lower chip. Note that, in the pixel examples shown in FIGS. 61 to 68, it is possible to receive return light emitted from a laser light source outside the pixel.

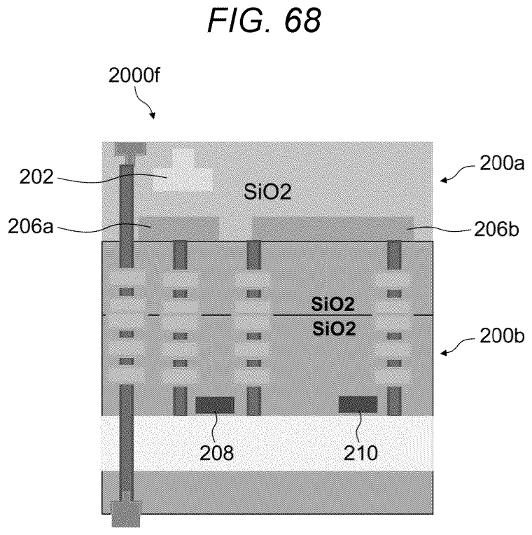

FIG. 68 is a cross-sectional view showing a configuration example of a pixel 2000f capable of infrared imaging. The pixel 2000f shown in FIG. 68 is different from the pixel 200 shown in FIG. 14 in having a through silicon via TSV connecting the upper end and the lower end and a Cu—Cu connection junction.

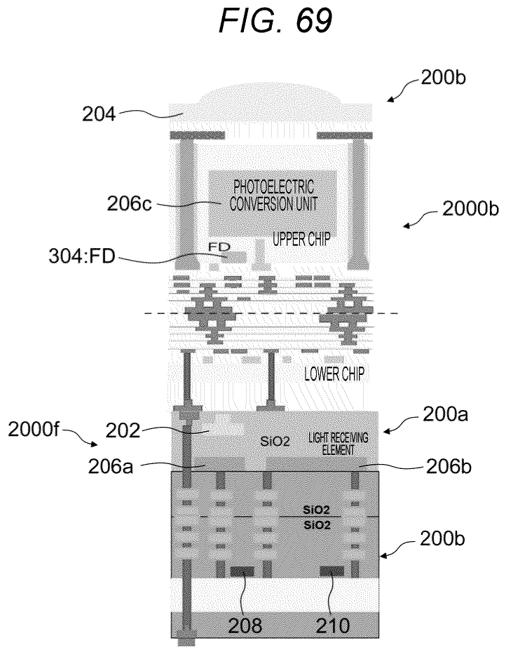

FIG. 69 is a cross-sectional view of a pixel in which the pixel 2000b capable of visible imaging and the pixel 2000f capable of infrared imaging are further stacked. Blue light, green light, and red light, which are visible light, are absorbed on the pixel 2000b side. However, since the near-infrared light having a long wavelength is not absorbed on the pixel 2000b side, the near-infrared light passes through the upper chip and is photoelectrically converted by the photoelectric conversion elements 206a and 206b of the lower chip. As a result, the return light of the light emitting unit 202 is received by the photoelectric conversion elements 206a and 206b of the lower chip.

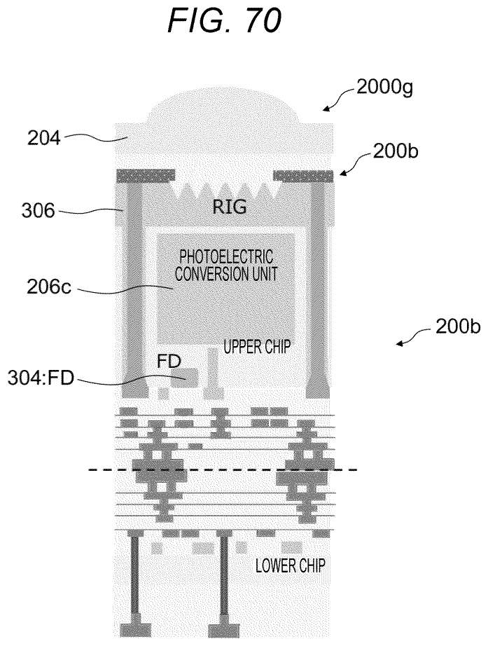

FIG. 70 is a diagram showing a configuration example of a pixel 2000g capable of visible imaging. As shown in FIG. 70, the configuration example is different from the pixel 2000b shown in FIG. 61 in further including a two-dimensional array-like optical diffraction structure (IPA, Inverted Pyramid Array) 306 having an inverse pyramid shape on the image sensor side. As a result, the photodetection element 206c also has sensitivity to near infrared rays of about 940 nm and 850 nm. Note that since silicon cannot absorb wavelengths of silicon with a band gap of 1100 nm or more, infrared rays of 1330 nm, 1550 nm, 2000 nm, and the like are not absorbed by the pixel 2000 g and are transmitted.

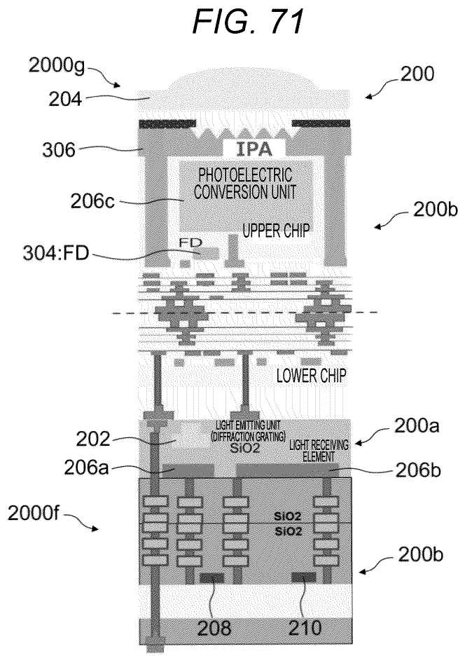

FIG. 71 is a cross-sectional view of a pixel in which the pixel 2000g capable of visible imaging and the pixel 2000f capable of infrared imaging are further stacked. Blue light, green light, and red light, which are visible light, are absorbed on the pixel 2000g side. However, since the near-infrared light having a long wavelength is not absorbed on the pixel 2000b side, the near-infrared light passes through the upper chip and is photoelectrically converted by the photoelectric conversion elements 206a and 206b of the lower chip. As a result, the return light of the light emitting unit 202 is received by the photoelectric conversion elements 206a and 206b of the lower chip.

As described above, according to the present embodiment, the light emitting unit 202 emits the measurement light in the first direction from the first region to the measurement target and emits the reference light in the second direction different from the first direction, and the photoelectric conversion elements 206a and 206b receive the reference light and convert the reference light into an electric signal. As a result, since the photoelectric conversion elements 206a and 206b directly receive the reference light, the pixel 200 can be downsized. Furthermore, the return light can be received by the photoelectric conversion elements 206a and 206b, and the reference light L14 and the return light L16 can be multiplexed by the photoelectric conversion elements 206a and 206b without using an optical fiber for multiplexing, an optical coupler, or the like. Therefore, the pixel 200 can be further downsized. As a result, the photodetection element 1 and the photodetection device 100 can be further downsized.

### Second Embodiment

Hereinafter, exemplary embodiments for carrying out the present technology will be described.

### <<1. Configuration Example of Vehicle Control System>>

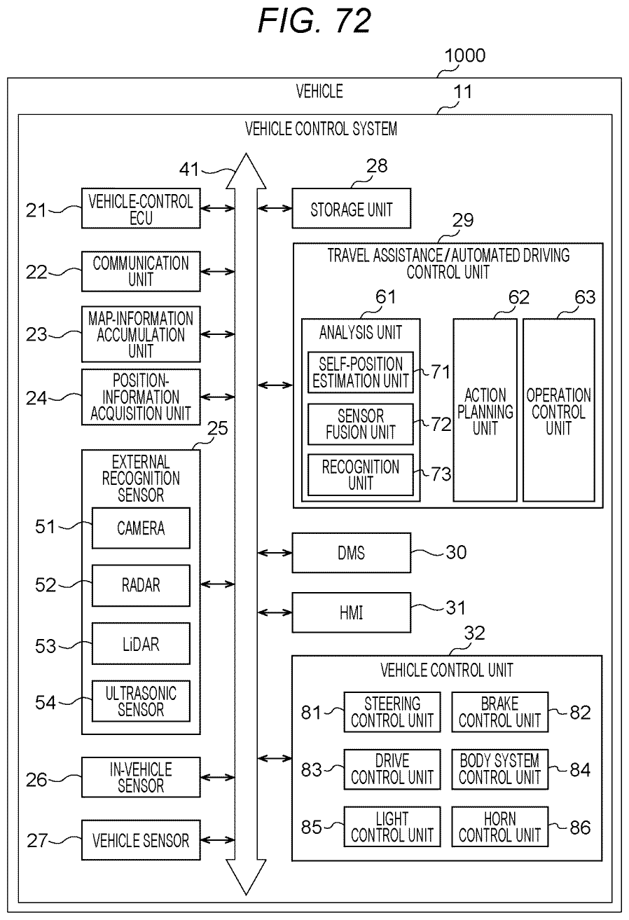

FIG. 72 is a block diagram showing a configuration example of a vehicle control system 11 that is an example of a mobile device control system to which the present technology is applied.

The vehicle control system 11 is provided in a vehicle 1000 and performs processing related to travel assistance and automated driving of the vehicle 1000. That is, the detection device 100 described above is applied to a LiDAR 53 described later included in the vehicle control system 11.

The vehicle control system 11 includes a vehicle-control electronic control unit (ECU) 21, a communication unit 22, a map-information accumulation unit 23, a position-information acquisition unit 24, an external recognition sensor 25, an in-vehicle sensor 26, a vehicle sensor 27, a storage unit 28, a travel assistance/automated driving control unit 29, a driver monitoring system (DMS) 30, a human machine interface (HMI) 31, and a vehicle control unit 32.

The vehicle control ECU 21, the communication unit 22, the map-information accumulation unit 23, the position-information acquisition unit 24, the external recognition sensor 25, the in-vehicle sensor 26, the vehicle sensor 27, the storage unit 28, the travel assistance/automated driving control unit 29, the driver monitoring system (DMS) 30, the human machine interface (HMI) 31, and the vehicle control unit 32 are communicably connected to each other via a communication network 41. The communication network 41 is formed by, for example, an in-vehicle communication network, a bus, or the like that conforms to a digital bidirectional communication standard such as controller area network (CAN), local interconnect network (LIN), local area network (LAN), FlexRay (registered trademark), and Ethernet (registered trademark). The communication network 41 may be selectively used depending on the type of data to be transmitted. For example, the CAN may be applied to data related to vehicle control, and the Ethernet may be applied to large-volume data. Note that units of the vehicle control system 11 may be directly connected to each other using wireless communication adapted to a relatively short-range communication, such as near field communication (NFC) or Bluetooth (registered trademark) without using the communication network 41.

Note that, hereinafter, in a case where each unit of the vehicle control system 11 performs communication via the communication network 41, the description of the communication network 41 will be omitted. For example, in a case where the vehicle control ECU 21 and the communication unit 22 perform communication via the communication network 41, it will be simply described that the vehicle control ECU 21 and the communication unit 22 perform communication.

For example, the vehicle control ECU 21 includes various processors such as a central processing unit (CPU) and a micro processing unit (MPU). The vehicle control ECU 21 controls all or some of the functions of the vehicle control system 11.

The communication unit 22 communicates with various devices inside and outside the vehicle, another vehicle, a server, a base station, and the like, and transmits and receives various data. At this time, the communication unit 22 can perform communication using a plurality of communication systems.

Communication with the outside of the vehicle executable by the communication unit 22 will be schematically described. The communication unit 22 communicates with a server (hereinafter, referred to as an external server) or the like present on an external network via a base station or an access point by, for example, a wireless communication system such as fifth generation mobile communication system (5G), long term evolution (LTE), dedicated short range communications (DSRC), or the like. Examples of the external network with which the communication unit 22 performs communication include the Internet, a cloud network, a company-specific network, and the like. The communication system by which the communication unit 22 communicates with the external network is not particularly limited as long as it is a wireless communication system allowing digital bidirectional communication at a communication speed equal to or higher than a predetermined speed and over a distance equal to or longer than a predetermined distance.

Furthermore, for example, the communication unit 22 can communicate with a terminal present in the vicinity of a host vehicle using a peer to peer (P2P) technology. The terminal present in the vicinity of the host vehicle is, for example, a terminal attached to a moving body moving at a relatively low speed such as a pedestrian or a bicycle, a terminal fixedly installed in a store or the like, or a machine type communication (MTC) terminal. Moreover, the communication unit 22 can also perform V2X communication. The V2X communication refers to, for example, communication between the host vehicle and another vehicle, such as vehicle to vehicle communication with another vehicle, vehicle to infrastructure communication with a roadside device or the like, vehicle to home communication, and vehicle to pedestrian communication with a terminal or the like carried by a pedestrian.

For example, the communication unit 22 can receive a program for updating software for controlling the operation of the vehicle control system 11 from the outside (Over The Air). The communication unit 22 can further receive map information, traffic information, the information regarding the surroundings of the vehicle 1000, or the like from the outside. Furthermore, for example, the communication unit 22 can transmit information regarding the vehicle 1000, information regarding the surroundings of the vehicle 1000, and the like to the outside. Examples of the information regarding the vehicle 1000 transmitted to the outside by the communication unit 22 include data indicating a state of the vehicle 1000, a recognition result from a recognition unit 73, or the like. Moreover, for example, the communication unit 22 performs communication corresponding to a vehicle emergency call system such as an eCall.

For example, the communication unit 22 receives an electromagnetic wave transmitted by a road traffic information communication system (vehicle information and communication system (VICS) (registered trademark)), such as a radio wave beacon, an optical beacon, or FM multiplex broadcasting.

Communication with the inside of the vehicle executable by the communication unit 22 will be schematically described. The communication unit 22 can communicate with each device in the vehicle using, for example, wireless communication. The communication unit 22 can perform wireless communication with a device in the vehicle by, for example, a communication system capable of performing digital bidirectional communication at a communication speed equal to or more than a predetermined speed by wireless communication, such as wireless LAN, Bluetooth, NFC, or wireless USB (WUSB). Communication performed by the communication unit 22 is not limited to wireless communication, and the communication unit 22 can also communicate with each device in the vehicle using wired communication. For example, the communication unit 22 can communicate with each device in the vehicle by wired communication via a cable connected to a connection terminal which is not shown. The communication unit 22 can communicate with each device in the vehicle by, for example, a communication system allowing digital bidirectional communication at a communication speed equal to or higher than a predetermined speed by wired communication, such as universal serial bus (USB), high-definition multimedia interface (HDMI) (registered trademark), or mobile high-definition link (MHL).

Here, the device in the vehicle refers to, for example, a device that is not connected to the communication network 41 in the vehicle. As the in-vehicle device, for example, a mobile apparatus or a wearable device carried by an occupant such as a driver, an information device carried onto a vehicle and temporarily installed, or the like can be considered.

The map-information accumulation unit 23 accumulates either or both of a map acquired from the outside and a map created by the vehicle 1000. For example, the map-information accumulation unit 23 accumulates a three-dimensional high-precision map, a global map that is lower in precision than the high-precision map but covers a wider area, and the like.

The high-precision map is, for example, a dynamic map, a point cloud map, a vector map, or the like. The dynamic map is, for example, a map including four layers of dynamic information, semi-dynamic information, semi-static information, and static information, and is provided to the vehicle 1000 from the external server or the like. The point cloud map is a map including a point cloud (point cloud data). The vector map is, for example, a map in which traffic information such as a lane and a position of a traffic light is associated with a point cloud map and adapted to an advanced driver assistance system (ADAS) or autonomous driving (AD).

The point cloud map and the vector map may be provided from, for example, the external server or the like, or may be created by the vehicle 1000 as a map for performing matching with a local map to be described later on the basis of a sensing result from a camera 51, a radar 52, a light detection and ranging or laser imaging detection and ranging (LiDAR) 53, or the like, and may be accumulated in the map-information accumulation unit 23. Furthermore, in a case where the high-precision map is provided from the external server or the like, for example, map data of several hundred meters square regarding a planned route on which the vehicle 1000 travels from now is acquired from the external server or the like in order to reduce the communication traffic.

The position-information acquisition unit 24 receives a global navigation satellite system (GNSS) signal from a GNSS satellite, and acquires position information of the vehicle 1000. The acquired position information is supplied to the travel assistance/automated driving control unit 29. Note that the position-information acquisition unit 24 may acquire the position information using not only a system using the GNSS signal, but also, for example, a beacon.

The external recognition sensor 25 includes various sensors used to recognize a situation outside the vehicle 1000, and supplies sensor data from each sensor to each unit of the vehicle control system 11. The type and number of sensors included in the external recognition sensor 25 may be determined as desired.

For example, the external recognition sensor 25 includes the camera 51, the radar 52, the light detection and ranging or laser imaging detection and ranging sensor (LiDAR) 53, and an ultrasonic sensor 54. It is not limited thereto, and the external recognition sensor 25 may include one or more types of sensors among the camera 51, the radar 52, the LiDAR 53, and the ultrasonic sensor 54. The number of cameras 51, the number of radars 52, the number of LiDARs 53, and the number of ultrasonic sensors 54 are not particularly limited as long as they can be practically installed in the vehicle 1000. Furthermore, the external recognition sensor 25 may include sensors of other types, but not limited to sensors of the types described in this example. An example of a sensing region of each sensor included in the external recognition sensor 25 will be described later.

Note that an imaging method of the camera 51 is not particularly limited. For example, cameras of various imaging methods such as a time of flight (ToF) camera, a stereo camera, a monocular camera, and an infrared camera, which are imaging methods capable of distance measurement, can be applied to the camera 51 as necessary. It is not limited thereto, and the camera 51 may simply acquire a captured image regardless of distance measurement.

Furthermore, for example, the external recognition sensor 25 can include an environment sensor for detecting an environment for the vehicle 1000. The environment sensor is a sensor for detecting an environment such as weather, climate, or brightness, and can include various sensors such as a raindrop sensor, a fog sensor, a sunshine sensor, a snow sensor, and an illuminance sensor, for example.

Moreover, for example, the external recognition sensor 25 includes a microphone used for detecting a sound around the vehicle 1000, a position of a sound source, and the like.

The in-vehicle sensor 26 includes various sensors for detecting information regarding the inside of the vehicle, and supplies sensor data from each sensor to each unit of the vehicle control system 11. The types and number of various sensors included in the in-vehicle sensor 26 are not particularly limited as long as they can be practically installed in the vehicle 1000.

For example, the in-vehicle sensor 26 can include one or more sensors of a camera, a radar, a seating sensor, a steering wheel sensor, a microphone, and a biological sensor. As the camera included in the in-vehicle sensor 26, for example, cameras of various imaging methods capable of measuring a distance, such as a ToF camera, a stereo camera, a monocular camera, and an infrared camera, can be used. In addition thereto, the camera included in the in-vehicle sensor 26 may be one that simply acquires a captured image without regard to distance measurement. The biological sensor included in the in-vehicle sensor 26 is provided, for example, on a seat, a steering wheel, or the like, and detects various kinds of biological information about an occupant such as a driver.

The vehicle sensor 27 includes various sensors for detecting the state of the vehicle 1000, and supplies the sensor data from each sensor to each unit of the vehicle control system 11. The types and number of various sensors included in the vehicle sensor 27 are not particularly limited as long as they can be practically installed in the vehicle 1000.

For example, the vehicle sensor 27 includes a speed sensor, an acceleration sensor, an angular velocity sensor (gyro sensor), and an inertial measurement unit (IMU) as an integrated sensor including these sensors. For example, the vehicle sensor 27 includes a steering angle sensor that detects a steering angle of a steering wheel, a yaw rate sensor, an accelerator sensor that detects an operation amount of an accelerator pedal, and a brake sensor that detects an operation amount of a brake pedal. For example, the vehicle sensor 27 includes a rotation sensor that detects the number of rotations of an engine or a motor, an air pressure sensor that detects the air pressure of a tire, a slip rate sensor that detects the slip rate of the tire, and a wheel speed sensor that detects the rotation speed of a wheel. For example, the vehicle sensor 27 includes a battery sensor that detects the state of charge and temperature of a battery, and an impact sensor that detects an external impact.

The storage unit 28 includes at least one of a nonvolatile storage medium or a volatile storage medium, and stores data and a program. The storage unit 28 is used as, for example, an electrically erasable programmable read only memory (EEPROM) and a random access memory (RAM), and a magnetic storage device such as a hard disc drive (HDD), a semiconductor storage device, an optical storage device, and a magneto-optical storage device can be applied as a storage medium. The storage unit 28 stores therein various programs and data used by each unit of the vehicle control system 11. For example, the storage unit 28 includes an event data recorder (EDR) and a data storage system for automated driving (DSSAD), and stores therein information regarding the vehicle 1000 before and after an event such as an accident and information acquired by the in-vehicle sensor 26. The travel assistance/automated driving control unit 29 controls travel assistance and automated driving of the vehicle 1000. For example, the travel assistance/automated driving control unit 29 includes an analysis unit 61, an action planning unit 62, and an operation control unit 63.

The analysis unit 61 executes analysis processing on the vehicle 1000 and a situation around the vehicle 1000. The analysis unit 61 includes a self-position estimation unit 71, a sensor fusion unit 72, and a recognition unit 73.

The self-position estimation unit 71 estimates a self-position of the vehicle 1000 on the basis of sensor data from the external recognition sensor 25 and the high-precision map accumulated in the map-information accumulation unit 23. For example, the self-position estimation unit 71 generates a local map on the basis of the sensor data from the external recognition sensor 25, and estimates the self-position of the vehicle 1000 by matching the local map with the high-precision map. The position of the vehicle 1000 is based on, for example, a center of a rear wheel pair axle.

The local map is, for example, a three-dimensional high-precision map created using a technology such as simultaneous localization and mapping (SLAM), an occupancy grid map, or the like. The three-dimensional high-precision map is, for example, the above-described point cloud map or the like. The occupancy grid map is a map in which a three-dimensional or two-dimensional space around the vehicle 1000 is divided into grids (lattices) with a predetermined size, and an occupancy state of an object is represented in units of grids. The occupancy state of the object is represented by, for example, presence or absence or an existence probability of the object. The local map is also used for detection processing and recognition processing on the situation outside the vehicle 1000 by the recognition unit 73, for example.

Note that the self-position estimation unit 71 may estimate the self-position of the vehicle 1000 on the basis of the position information acquired by the position-information acquisition unit 24 and sensor data from the vehicle sensor 27.

The sensor fusion unit 72 performs sensor fusion processing of combining a plurality of different kinds of sensor data (for example, image data supplied from the camera 51 and sensor data supplied from the radar 52), to acquire new information. Methods for combining different types of sensor data include integration, fusion, association, or the like.

The recognition unit 73 executes detection processing for detecting the situation outside the vehicle 1000 and recognition processing for recognizing the situation outside the vehicle 1000.

For example, the recognition unit 73 executes the detection processing and the recognition processing on the situation outside the vehicle 1000 on the basis of information from the external recognition sensor 25, information from the self-position estimation unit 71, information from the sensor fusion unit 72, and the like.

Specifically, for example, the recognition unit 73 executes detection processing, recognition processing, and the like on an object around the vehicle 1000. The object detection processing is, for example, processing for detecting presence or absence, size, shape, position, motion, or the like of an object. The object recognition processing is, for example, processing for recognizing an attribute such as a type of an object or identifying a specific object. The detection processing and the recognition processing, however, are not necessarily clearly separated and may overlap.

For example, the recognition unit 73 detects an object around the vehicle 1000 by performing clustering to classify point clouds based on sensor data from the LiDAR 53, the radar 52, or the like into clusters of point clouds. Thus, the presence or absence, size, shape, and position of the object around the vehicle 1000 are detected.

For example, the recognition unit 73 detects a motion of the object around the vehicle 1000 by performing tracking for following a motion of the cluster of the point cloud classified by clustering. Thus, the speed and the traveling direction (movement vector) of the object around the vehicle 1000 are detected.

For example, the recognition unit 73 detects or recognizes a vehicle, a person, a bicycle, an obstacle, a structure, a road, a traffic light, a traffic sign, a road sign, and the like on the basis of the image data supplied from the camera 51. Furthermore, the recognition unit 73 may recognize the type of the object around the vehicle 1000 by executing recognition processing such as semantic segmentation.

For example, the recognition unit 73 can execute recognition processing on traffic rules around the vehicle 1000 on the basis of a map accumulated in the map-information accumulation unit 23, a result of estimation of the self-position by the self-position estimation unit 71, and a result of recognition of an object around the vehicle 1000 by the recognition unit 73. Through this processing, the recognition unit 73 can recognize the position and the state of the traffic light, the details of the traffic sign and the road sign, the details of the traffic regulation, the travelable lane, and the like.

For example, the recognition unit 73 can execute the recognition processing on a surrounding environment of the vehicle 1000. As the surrounding environment to be recognized by the recognition unit 73, weather, temperature, humidity, brightness, road surface conditions, and the like are assumed.

The action planning unit 62 creates an action plan for the vehicle 1000. For example, the action planning unit 62 creates an action plan by executing processing of route planning and route following.

Note that the route planning (global path planning) is processing of planning a rough route from a start to a goal. This route planning is called a trajectory plan, and includes processing of creating a trajectory (local path planning) that enables safe and smooth traveling in the vicinity of the vehicle 1000 in consideration of the motion characteristics of the vehicle 1000 in the planned route.

The route following is processing of planning an operation for safely and accurately traveling a route planned by the route planning within a planned time. For example, the action planning unit 62 can calculate a target speed and a target angular velocity of the vehicle 1000, on the basis of a result of the processing of route following.

The operation control unit 63 controls the operation of the vehicle 1000 in order to achieve the action plan created by the action planning unit 62.

For example, the operation control unit 63 controls a steering control unit 81, a brake control unit 82, and a drive control unit 83 included in the vehicle control unit 32 to be described later, to control acceleration/deceleration and the direction so that the vehicle 1000 travels on a trajectory calculated by trajectory planning. For example, the operation control unit 63 performs coordinated control for the purpose of implementing the functions of the ADAS such as collision avoidance or impact mitigation, follow-up traveling, vehicle-speed maintaining traveling, warning of collision of an own vehicle, warning of lane deviation of an own vehicle, and the like. For example, the operation control unit 63 performs coordinated control for the purpose of automated driving or the like in which a vehicle autonomously travels without depending on the operation of a driver.

The DMS 30 executes authentication processing on the driver, recognition processing on a state of the driver, and the like on the basis of sensor data from the in-vehicle sensor 26, input data input to the HMI 31 to be described later, and the like. As the state of the driver to be recognized, for example, a physical condition, an alertness level, a concentration level, a fatigue level, a line-of-sight direction, a drunkenness level, a driving operation, a posture, and the like are assumed.

Note that the DMS 30 may perform processing of authenticating an occupant other than a driver, and a process of recognizing a condition of the occupant. Furthermore, for example, the DMS 30 may execute recognition processing on the conditions inside the vehicle on the basis of sensor data from the in-vehicle sensor 26. As the situation in the vehicle to be recognized, for example, a temperature, a humidity, brightness, odor, or the like are assumed.

The HMI 31 receives various data, instructions, and the like, and presents various data to a driver and the like.

The input of data through the HMI 31 will be schematically described. The HMI 31 includes an input device for a person to input data. The HMI 31 generates an input signal on the basis of data, an instruction, or the like input with the input device, and supplies the input signal to each unit of the vehicle control system 11. The HMI 31 includes, for example, an operation element such as a touch panel, a button, a switch, and a lever as the input device. It is not limited thereto, and the HMI 31 may further include an input device capable of inputting information by a method such as voice, gesture, or the like other than manual operation. Moreover, the HMI 31 may use, for example, a remote control device using infrared rays or radio waves, or an external connection device such as a mobile device or a wearable device adapted to the operation of the vehicle control system 11 as an input device.

Presentation of data by the HMI 31 will be schematically described. The HMI 31 generates visual information, auditory information, and haptic information regarding an occupant or the outside of a vehicle. Furthermore, the HMI 31 performs output control for controlling the output, output content, output timing, output method, and the like of each piece of generated information. The HMI 31 generates and outputs, as the visual information, an operation screen, a state display of the vehicle 1000, a warning display, an image such as a monitor image indicating a situation around the vehicle 1000, and information indicated by light, for example. Furthermore, the HMI 31 generates and outputs, as the auditory information, information indicated by sounds such as voice guidance, a warning sound, and a warning message, for example. Moreover, the HMI 31 generates and outputs, for example, information given to the sense of touch of an occupant through force, vibration, motion, or the like, as haptic information.

As an output device that the HMI 31 outputs the visual information, for example, a display device that presents the visual information by displaying an image by itself or a projector device that presents the visual information by projecting an image can be applied. Note that the display device may be a device that displays the visual information in the field of view of the occupant, such as a head-up display, a transmissive display, or a wearable device having an augmented reality (AR) function, for example, in addition to a display device having an ordinary display. Furthermore, in the HMI 31, a display device included in a navigation device, an instrument panel, a camera monitoring system (CMS), an electronic mirror, a lamp, or the like provided in the vehicle 1000 can also be used as the output device that outputs the visual information.

As an output device from which the HMI 31 outputs the auditory information, for example, an audio speaker, a headphone, or an earphone can be applied.

As an output device to which the HMI 31 outputs the tactile information, for example, a haptic element using a haptic technology can be applied. The haptic element is provided, for example, in a portion to be touched by the occupant of the vehicle 1000, such as a steering wheel or a seat.

The vehicle control unit 32 controls each unit of the vehicle 1000. The vehicle control unit 32 includes the steering control unit 81, the brake control unit 82, the drive control unit 83, a body system control unit 84, a light control unit 85, and a horn control unit 86.

The steering control unit 81 performs detection, control, and the like of a state of a steering system of the vehicle 1000. The steering system includes, for example, a steering mechanism including a steering wheel or the like, an electric power steering, or the like. The steering control unit 81 includes, for example, a steering ECU that controls the steering system, an actuator that drives the steering system, and the like.

The brake control unit 82 performs detection, control, and the like of a state of a brake system of the vehicle 1000. The brake system includes, for example, a brake mechanism including a brake pedal or the like, an antilock brake system (ABS), a regenerative brake mechanism, or the like. The brake control unit 82 includes, for example, a brake ECU that controls the brake system, an actuator that drives the brake system, and the like.

The drive control unit 83 performs detection, control, and the like of a state of a drive system of the vehicle 1000. The drive system includes, for example, an accelerator pedal, a driving force generation device for generating a driving force such as an internal combustion engine or a driving motor, a driving force transmission mechanism for transmitting the driving force to wheels, or the like. The drive control unit 83 includes, for example, a drive ECU that controls the drive system, an actuator that drives the drive system, and the like.

The body system control unit 84 performs detection, control, and the like of a state of a body system of the vehicle 1000. The body system includes, for example, a keyless entry system, a smart key system, a power window device, a power seat, an air conditioner, an airbag, a seat belt, a shift lever, or the like. The body system control unit 84 includes, for example, a body system ECU that controls the body system, an actuator that drives the body system, and the like.

The light control unit 85 performs detection, control, and the like of states of various lights of the vehicle 1000. As the lights to be controlled, for example, a headlight, a backlight, a fog light, a turn signal, a brake light, a projection light, a bumper indicator, or the like can be considered. The light control unit 85 includes a light ECU that controls the lights, an actuator that drives the lights, and the like.

The horn control unit 86 performs detection, control, and the like of a state of a car horn of the vehicle 1000. The horn control unit 86 includes, for example, a horn ECU that controls the car horn, an actuator that drives the car horn, and the like.

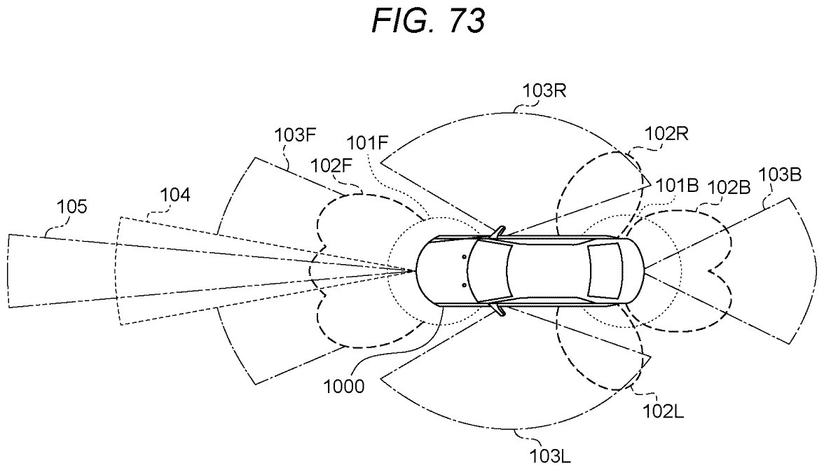

FIG. 73 is a diagram showing examples of sensing regions of the camera 51, the radar 52, the LiDAR 53, the ultrasonic sensor 54, and the like of the external recognition sensor 25 in FIG. 72. Note that FIG. 73 schematically shown the vehicle 1000 as viewed from above, where a left end side is the front end (front) side of the vehicle 1000, and a right end side is the rear end (rear) side of the vehicle 1000.

Sensing regions 101F and 101B show examples of sensing regions of the ultrasonic sensor 54. The sensing region 101F covers a region around the front end of the vehicle 1000 by the plurality of ultrasonic sensors 54. The sensing region 101B covers a region around the rear end of the vehicle 1000 by the plurality of ultrasonic sensors 54.

Sensing results in the sensing region 101F and the sensing region 101B are used for, for example, parking assistance and the like of the vehicle 1000.

Sensing regions 102F to 102B show examples of sensing regions of the radar 52 for a short range or a medium range. The sensing region 102F covers a position farther than the sensing region 101F, on the front side of the vehicle 1000. The sensing region 102B covers a position farther than the sensing region 101B, on the rear side of the vehicle 1000. The sensing region 102L covers a region around the rear side of a left side surface of the vehicle 1000. The sensing region 102R covers a region around the rear side of a right side surface of the vehicle 1000.

A sensing result in the sensing region 102F is used for, for example, detection of a vehicle, a pedestrian, or the like existing on the front side of the vehicle 1000, or the like. A sensing result in the sensing region 102B is used for, for example, a function for preventing a collision of the rear side of the vehicle 1000, or the like. Sensing results in the sensing regions 102L and 102R are used for, for example, detection of an object in a blind spot on the sides of the vehicle 1000, and the like.

Sensing regions 103F to 103B show examples of sensing regions of the camera 51. The sensing region 103F covers a position farther than the sensing region 102F, on the front side of the vehicle 1000. The sensing region 103B covers a position farther than the sensing region 102B, on the rear side of the vehicle 1000. The sensing region 103L covers a region around the left side surface of the vehicle 1000. The sensing region 103R covers a region around the right side surface of the vehicle 1000.

A sensing result in the sensing region 103F can be used for, for example, recognition of a traffic light or a traffic sign, a lane departure prevention assist system, and an automatic headlight control system. A sensing result in the sensing region 103B is used for, for example, parking assistance, a surround view system, and the like. Sensing results in the sensing regions 103L and 103R can be used for, for example, a surround view system.

A sensing region 104 shown an example of a sensing region of the LiDAR 53. The sensing region 104 covers a position farther than the sensing region 103F, on the front side of the vehicle 1000. Meanwhile, the sensing region 104 has a narrower range in a left-right direction than the sensing region 103F.

A sensing result in the sensing region 104 is used for, for example, detection of an object such as a neighboring vehicle.

A sensing region 105 shows an example of a sensing region of the radar 52 for a long range. The sensing region 105 covers a position farther than the sensing region 104, on the front side of the vehicle 1000. Meanwhile, the sensing region 105 has a narrower range in the left-right direction than the sensing region 104.

A result of sensing in the sensing region 105 is used, for example, for adaptive cruise control (ACC), emergency braking, collision avoidance, and the like.

Note that the respective sensing regions of the sensors: the camera 51; the radar 52; the LiDAR 53; and the ultrasonic sensor 54, included in the external recognition sensor 25 may have various configurations other than those in FIG. 73. Specifically, the ultrasonic sensor 54 may also perform sensing on the sides of the vehicle 1000, or the LiDAR 53 may perform sensing on the rear of the vehicle 1000. Furthermore, an installation position of each sensor is not limited to each example described above. Furthermore, the number of sensors may be one or plural.

Note that the present technology can have the following configurations.

(1)

A photodetection element, including:
a light emitting unit configured to emit measurement light in a first direction to a measurement target and emit reference light in a second direction different from the first direction; and
a photoelectric conversion element configured to receive the reference light and performs photoelectric conversion.

(2)

The photodetection element according to (1), in which the photoelectric conversion element further receives return light of the measurement light from the measurement target, and photoelectrically converts the reference light and the return light.

(3)

The photodetection element according to (1), in which the second direction is a direction opposite to the first direction.

(4)

The photodetection element according to (1), in which the light emitting unit emits the measurement light from a first region to a measurement target, and emits the reference light from a second region different from the first region.

(5)

The photodetection element according to (4), in which the second region is a region of a surface opposite to a traveling direction of the measurement light emitted from the first region.

(6)

The photodetection element according to (1), in which the light emitting unit emits light having a wavelength longer than 700 nm.

(7)

The photodetection element according to (6), in which the light emitting unit is a material having a band gap equal to or more than energy corresponding to the wavelength of the emitted light.

(8)

The photodetection element according to (1), in which the light emitting unit includes at least one of silicon (Si), silicon nitride (Si₃N₄), gallium nitrate (Ga₂O₃), and germanium (Ge).

(9)

The photodetection element according to (1),
in which the light emitting unit is a diffraction grating including a diffraction portion, and
the measurement light is emitted from the diffraction grating.

(10)

The photodetection element according to (1), in which the light emitting unit includes an optical switch using a micro electro mechanical system (MEMS).

(11)

The photodetection element according to (1), in which the light emitting unit emits chirped light having a chirped frequency as the measurement light.

(12)

The photodetection element according to (1), in which return light of the measurement light from the measurement target is received by the photoelectric conversion element via a plurality of lenses.

(13)

The photodetection element according to (9), in which the photoelectric conversion element is made of a material that absorbs light emitted from the diffraction grating.

(14)

The photodetection element according to (1), in which the photoelectric conversion element includes at least one of germanium (Ge), silicon germanium (SiGe), indium gallium arsenide (InGaAs), gain (GaInAsP), erbium-doped gallium arsenide (GaAs:Er), erbium-doped indium arsenide (InP:Er), carbon-doped silicon (Si: C), gallium antimonide (GaSb), indium arsenide (InAs), indium arsenide antimony phosphorus (InAsSbP), and gallium oxide (Ga₂O₃).

(15)

The photodetection element according to (1), further including a readout circuit unit configured to convert an output signal of the photoelectric conversion element into a digital signal,
in which the photodetection element has a stacked structure in which the light emitting unit, the photodetection element, and the readout circuit unit are stacked in this order.

(16)

The photodetection element according to (15), in which the readout circuit unit is configured on a silicon-on-insulator (SOI) substrate having a structure including silicon oxide (SiO₂) between a silicon (Si) substrate and a silicon (Si) layer as a surface layer.

(17)

The photodetection element according to (15), in which the readout circuit unit is electrically connected to a detection circuit board.

(18)

The photodetection element according to (15), in which the readout circuit unit is electrically connected to a detection element that detects visible light.

(19)

The photodetection element according to (1), in which the photoelectric conversion element includes a balanced photodiode.

(20)

The photodetection element according to (1), in which a lens is formed on the photoelectric conversion element.

(21)

The photodetection element according to (20), in which one or more lenses are arranged for one photodetection element.

(22)

The photodetection element according to (1), in which a curved surface lens having an uneven structure is formed on the photoelectric conversion element.

(23)

The photodetection element according to (1), in which a metalens is formed on the photoelectric conversion element. (24)

The photodetection element according to (1), in which a plurality of the photoelectric conversion elements is arranged in a two-dimensional lattice pattern.

(25)

The photodetection element according to (24), further including a readout circuit unit configured to convert an output signal of the photoelectric conversion element into a digital signal,
in which the readout circuit unit includes:
a trans-impedance amplifier configured to amplify an output signal of the photoelectric conversion element; and
an analog-to-digital converter configured to convert an output signal of the trans-impedance amplifier into a digital signal.

(26)

The photodetection element according to (25), in which the trans-impedance amplifier and the analog-to-digital converter are arranged for each of the photoelectric conversion elements.

(27)

The photodetection element according to (25), in which one trans-impedance amplifier is disposed for each of the plurality of photoelectric conversion elements.

(28)

The photodetection element according to (25), in which one analog-to-digital converter is arranged for each of the plurality of photoelectric conversion elements.

(29)

The photodetection element according to (28), in which the light emitting unit, the photoelectric conversion element, and the readout circuit unit are stacked in this order.

(30)

The photodetection element according to (29), in which the light emitting unit corresponds to the photoelectric conversion element, and at least one light emitting unit is arranged for one photoelectric conversion element.

(31)

The photodetection element according to (29), in which the light emitting unit corresponds to a plurality of the photoelectric conversion elements, and at least one row of the light emitting unit is arranged for the plurality of photoelectric conversion elements.

(32)

The photodetection element according to (28) in which light emitting unit, the photoelectric conversion element, and the readout circuit unit are configured on a silicon-on-insulator (SOI) substrate.

(33)

The photodetection element according to (28), in which the light emitting unit, the photoelectric conversion element, and the readout circuit unit are connected by metal wiring.

(34)

The photodetection element according to (1), further including a second photoelectric conversion element configured to detect visible light,
in which the second photoelectric conversion element is disposed on a light incident side with respect to the photoelectric conversion element.

(35)

A photodetection device, including:
the photodetection element according to (1); and
a light source of the measurement light.

(36)

The photodetection device according to (35),
in which a plurality of the photoelectric conversion elements is arranged in a two-dimensional lattice pattern, and
the light emitting units are arranged corresponding to the plurality of photoelectric conversion elements arranged in the lattice pattern.

(37)

The photodetection device according to (36), further including a control unit that is disposed corresponding to the photoelectric conversion element and is configured to control light emission of the light emitting unit.

(38)

The photodetection device according to (37), in which the control unit performs control to cause the light emitting units corresponding to the plurality of the photoelectric conversion elements so as to emit light at the same timing.

(39)

The photodetection device according to (37), in which the control unit controls the light emitting units corresponding to the plurality of the photoelectric conversion elements arranged in rows so as to change rows while emitting light.

(40)

The photodetection device according to (37), in which the control unit controls the light emitting units corresponding to the plurality of the photoelectric conversion elements arranged in a plurality of rows so as to change rows while emitting light.

(41)

The photodetection device according to (37), in which the control unit causes the light emitting units corresponding to the plurality of the photoelectric conversion elements to emit light, and further converts output signals of some of the photoelectric conversion elements among the plurality of photoelectric conversion elements into digital signals.

(42)

A photodetection element including:
a first photoelectric conversion element configured to detect infrared light; and
a second photoelectric conversion element configured to detect visible light,
in which the second photoelectric conversion element is disposed on a light incident side with respect to the first photoelectric conversion element.

(43)

The photodetection element according to (42), further including a third photoelectric conversion element configured to detect infrared light in a wavelength band different from a wavelength band of the first photoelectric conversion element.

(44)

The photodetection element according to (43), in which the third photoelectric conversion element and the second photoelectric conversion element are stacked.

(45)

The photodetection element according to (42), further including a two-dimensional array-like optical diffraction structure portion having an inverse pyramid shape,
in which the optical diffraction structure portion is disposed on a light incident side of the second photoelectric conversion element.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1 Photodetection element
11a, 11b Laser light source
100 Photodetection device
200 Pixel
200a Optical circuit unit
200b Readout circuit unit
202 Light emitting unit
204 Microlens
206a, 206b, 206c Photoelectric conversion element
208 Trans-impedance amplifier
210 Analog-to-digital conversion circuit

1. A photodetection element, comprising:
a light emitting unit configured to emit measurement light in a first direction to a measurement target and emit reference light in a second direction different from the first direction; and
a photoelectric conversion element configured to receive the reference light and performs photoelectric conversion.

2. The photodetection element according to claim 1, wherein the photoelectric conversion element further receives return light of the measurement light from the measurement target, and photoelectrically converts the reference light and the return light.

3. The photodetection element according to claim 1, wherein the second direction is a direction opposite to the first direction.

4. The photodetection element according to claim 1, wherein the light emitting unit emits the measurement light from a first region to a measurement target, and emits the reference light from a second region different from the first region.

5. The photodetection element according to claim 4, wherein the second region is a region of a surface opposite to a traveling direction of the measurement light emitted from the first region.

6. The photodetection element according to claim 1, wherein the light emitting unit emits light having a wavelength longer than 700 nm.

7. The photodetection element according to claim 6, wherein the light emitting unit is a material having a band gap equal to or more than energy corresponding to the wavelength of the emitted light.

8. The photodetection element according to claim 1, wherein the light emitting unit includes at least one of silicon (Si), silicon nitride (Si₃N₄), gallium nitrate (Ga₂O₃), and germanium (Ge).

9. The photodetection element according to claim 1,
wherein the light emitting unit is a diffraction grating including a diffraction portion, and
the measurement light is emitted from the diffraction grating.

10. The photodetection element according to claim 1, wherein the light emitting unit includes an optical switch using a micro electro mechanical system (MEMS).

11. The photodetection element according to claim 1, wherein the light emitting unit emits chirped light having a chirped frequency as the measurement light.

12. The photodetection element according to claim 1, wherein return light of the measurement light from the measurement target is received by the photoelectric conversion element via a plurality of lenses.

13. The photodetection element according to claim 9, wherein the photoelectric conversion element is made of a material that absorbs light emitted from the diffraction grating.

14. The photodetection element according to claim 1, wherein the photoelectric conversion element includes at least one of germanium (Ge), silicon germanium (SiGe), indium gallium arsenide (InGaAs), gain (GaInAsP), erbium-doped gallium arsenide (GaAs:Er), erbium-doped indium arsenide (InP:Er), carbon-doped silicon (Si: C), gallium antimonide (GaSb), indium arsenide (InAs), indium arsenide antimony phosphorus (InAsSbP), and gallium oxide (Ga₂O₃).

15. The photodetection element according to claim 1, further comprising a readout circuit unit configured to convert an output signal of the photoelectric conversion element into a digital signal,
wherein the photodetection element has a stacked structure in which the light emitting unit, the photodetection element, and the readout circuit unit are stacked in this order.

16. The photodetection element according to claim 15, wherein the readout circuit unit is configured on a silicon-on-insulator (SOI) substrate having a structure including silicon oxide (SiO₂) between a silicon (Si) substrate and a silicon (Si) layer as a surface layer.

17. The photodetection element according to claim 15, wherein the readout circuit unit is electrically connected to a detection circuit board.

18. The photodetection element according to claim 15, wherein the readout circuit unit is electrically connected to a detection element that detects visible light.

19. The photodetection element according to claim 1, wherein the photoelectric conversion element includes a balanced photodiode.

20. The photodetection element according to claim 1, wherein a lens is formed on the photoelectric conversion element.

21. The photodetection element according to claim 20, wherein one or more lenses are arranged for one photodetection element.

22. The photodetection element according to claim 1, wherein a curved surface lens having an uneven structure is formed on the photoelectric conversion element.

23. The photodetection element according to claim 1, wherein a metalens is formed on the photoelectric conversion element.

24. The photodetection element according to claim 1, wherein a plurality of the photoelectric conversion elements is arranged in a two-dimensional lattice pattern.

25. The photodetection element according to claim 24, further comprising a readout circuit unit configured to convert an output signal of the photoelectric conversion element into a digital signal,
wherein the readout circuit unit includes:
a trans-impedance amplifier configured to amplify an output signal of the photoelectric conversion element; and
an analog-to-digital converter configured to convert an output signal of the trans-impedance amplifier into a digital signal.

26. The photodetection element according to claim 25, wherein the trans-impedance amplifier and the analog-to-digital converter are arranged for each of the photoelectric conversion elements.

27. The photodetection element according to claim 25, wherein one trans-impedance amplifier is disposed for each of the plurality of photoelectric conversion elements.

28. The photodetection element according to claim 25, wherein one analog-to-digital converter is arranged for each of the plurality of photoelectric conversion elements.

29. The photodetection element according to claim 28, wherein the light emitting unit, the photoelectric conversion element, and the readout circuit unit are stacked in this order.

30. The photodetection element according to claim 29, wherein the light emitting unit corresponds to the photoelectric conversion element, and at least one light emitting unit is arranged for one photoelectric conversion element.

31. The photodetection element according to claim 29, wherein the light emitting unit corresponds to a plurality of the photoelectric conversion elements, and at least one row of the light emitting unit is arranged for the plurality of photoelectric conversion elements.

32. The photodetection element according to claim 28, wherein the light emitting unit, the photoelectric conversion element, and the readout circuit unit are configured on a silicon-on-insulator (SOI) substrate.

33. The photodetection element according to claim 28, wherein the light emitting unit, the photoelectric conversion element, and the readout circuit unit are connected by metal wiring.

34. The photodetection element according to claim 1, further comprising a second photoelectric conversion element configured to detect visible light,
wherein the second photoelectric conversion element is disposed on a light incident side with respect to the photoelectric conversion element.

35. A photodetection device, comprising:
the photodetection element according to claim 1; and
a light source of the measurement light.

36. The photodetection device according to claim 35,
wherein a plurality of the photoelectric conversion elements is arranged in a two-dimensional lattice pattern, and
the light emitting units are arranged corresponding to the plurality of photoelectric conversion elements arranged in the lattice pattern.

37. The photodetection device according to claim 36, further comprising a control unit that is disposed corresponding to the photoelectric conversion element and is configured to control light emission of the light emitting unit.

38. The photodetection device according to claim 37, wherein the control unit performs control to cause the light emitting units corresponding to the plurality of the photoelectric conversion elements so as to emit light at the same timing.

39. The photodetection device according to claim 37, wherein the control unit controls the light emitting units corresponding to the plurality of the photoelectric conversion elements arranged in rows so as to change rows while emitting light.

40. The photodetection device according to claim 37, wherein the control unit controls the light emitting units corresponding to the plurality of the photoelectric conversion elements arranged in a plurality of rows so as to change rows while emitting light.

41. The photodetection device according to claim 37, wherein the control unit causes the light emitting units corresponding to the plurality of the photoelectric conversion elements to emit light, and further converts output signals of some of the photoelectric conversion elements among the plurality of photoelectric conversion elements into digital signals.

42. A photodetection element comprising:
a first photoelectric conversion element configured to detect infrared light; and
a second photoelectric conversion element configured to detect visible light,
wherein the second photoelectric conversion element is disposed on a light incident side with respect to the first photoelectric conversion element.

43. The photodetection element according to claim 42, further comprising a third photoelectric conversion element configured to detect infrared light in a wavelength band different from a wavelength band of the first photoelectric conversion element.

44. The photodetection element according to claim 43, wherein the third photoelectric conversion element and the second photoelectric conversion element are stacked.

45. The photodetection element according to claim 42, further comprising a two-dimensional array-like optical diffraction structure portion having an inverse pyramid shape,
wherein the optical diffraction structure portion is disposed on a light incident side of the second photoelectric conversion element.
